(19) United States
(12) Patent Application Publication
(10) Pub. No.: US 2018/0198080 A1
(43) Pub. Date: Jul. 12, 2018

(54) ORGANOMETALLIC COMPOUND, COMPOSITION CONTAINING THE ORGANOMETALLIC COMPOUND, AND ORGANIC LIGHT-EMITTING DEVICE

(71) Applicants: Samsung Electronics Co., Ltd., Suwon-si (KR); Samsung SDI Co., Ltd., Yongin-si (KR)

(72) Inventors: Changho NOH, Suwon-si (KR); Sunghan KIM, Seongnam-si (KR); Wook KIM, Suwon-si (KR); Taerae KIM, Suwon-si (KR); Sangho PARK, Anyang-si (KR); Won-Joon SON, Yongin-si (KR); Jhunmo SON, Yongin-si (KR); Dalho HUH, Suwon-si (KR); Virendra Kumar RAI, Hwaseong-si (KR); Satoko ISHIBE, Seongnam-si (KR); Jaejun CHANG, Seoul (KR)

(21) Appl. No.: 15/867,867

(22) Filed: Jan. 11, 2018

(30) Foreign Application Priority Data
Jan. 11, 2017 (KR) 10-2017-0004165

(51) Int. Cl. H01L 51/00; C07F 15/00; C09K 11/06

(52) U.S. Cl. CPC H01L 51/0085; C07F 15/0033; H01L 51/5024; H01L 51/0072; C09K 11/06

(57) ABSTRACT

An organometallic compound represented by Formula 1:

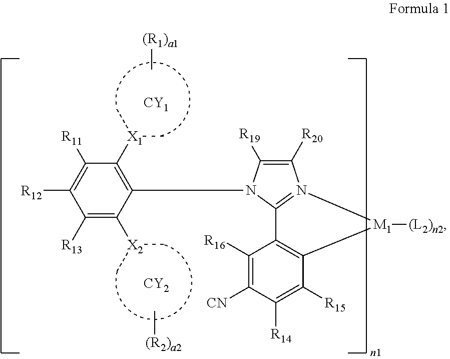

wherein, in Formula 1, groups and variables are the same as described in the specification.

### CROSS-REFERENCE TO RELATED APPLICATION

This application claims priority to Korean Patent Application No. 10-2017-0004165, filed on Jan. 11, 2017, in the Korean Intellectual Property Office, and all the benefits accruing therefrom under 35 U.S.C. § 119, the content of which is incorporated herein in its entirety by reference.

### BACKGROUND

### 1. Field

One or more embodiments relate to an organometallic compound, a composition containing the organometallic compound, and an organic light-emitting device.

### 2. Description of the Related Art

Organic light-emitting devices (OLEDs) are self-emission devices, which produce full-color images, and which have wide viewing angles, high contrast ratios, short response times, and excellent characteristics in terms of brightness, driving voltage, and response speed, compared to the devices in the art.

In an example, an organic light-emitting device includes an anode, a cathode, and an organic layer disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. The holes and the electrons recombine in the emission layer to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

One or more embodiments include a novel organometallic compound, a composition containing the organometallic compound, and an organic light-emitting device.

Additional aspects will be set forth in part in the description which follows and, in part, will be apparent from the description, or may be learned by practice of the presented embodiments.

According to one or more embodiments, an organometallic compound is represented by Formula 1:

Formula 1

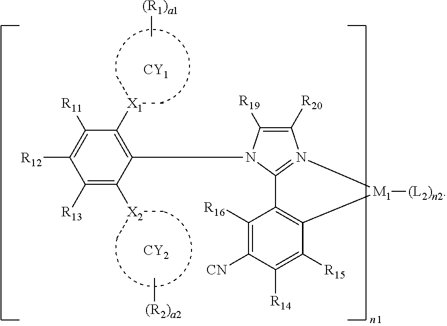

In Formula 1,
M₁ may be selected from a first-row transition metal of the Periodic Table of Elements, a second-row transition metal of the Periodic Table of Elements, and a third-row transition metal of the Periodic Table of Elements,
n1 may be 1, 2, or 3,
L₂ may be selected from a monodentate ligand and a bidentate ligand,
n2 may be 0, 1, 2, 3, or 4, wherein, when n2 is two or more, two or more groups L₂ may be identical to or different from each other,
X₁ and X₂ may each independently be carbon or nitrogen,
CY₁ and CY₂ may each independently be selected from a C₅-C₃₀ carbocyclic group and a C₂-C₃₀ heterocyclic group,
R₁, R₂, and R₁₁ to R₁₆ may each independently be selected from hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₁, R₂, R₁₁ to R₁₃, CY₁, and CY₂ may optionally be linked to form a substituted or unsubstituted C₅-C₃₀ carbocyclic group or a substituted or unsubstituted C₂-C₃₀ heterocyclic group,
a1 and a2 may each independently be an integer from 0 to 5,
R₁₉ and R₂₀ may each independently be selected from hydrogen, deuterium, a C₁-C₃₀ alkyl group, a C₁-C₃₀ alkyl group substituted with at least one deuterium, a C₆-C₆₀ aryl group, and a C₆-C₆₀ aryl group substituted with at least one selected from a C₁-C₃₀ alkyl group and deuterium,
at least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, and the substituted monovalent non-aromatic condensed heteropolycyclic group may be selected from:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), and —P(═O)(Q₁₈)(Q₁₉);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), and —P(═O)(Q₂₈)(Q₂₉); and
—N(Q₃₁)(Q₃₂), —Si(Q₃₃)(Q₃₄)(Q₃₅), —B(Q₃₆)(Q₃₇), and —P(═O)(Q₃₈)(Q₃₉),
wherein Q₁ to Q₉, Q₁₁ to Q₁₉, Q₂₁ to Q₂₉, and Q₃₁ to Q₃₉ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one selected from a C₁-C₆₀ alkyl group and a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group.

According to one or more embodiments, a composition containing the organometallic compound includes a first organometallic compound represented by Formula 1 and a second organometallic compound represented by Formula 2:

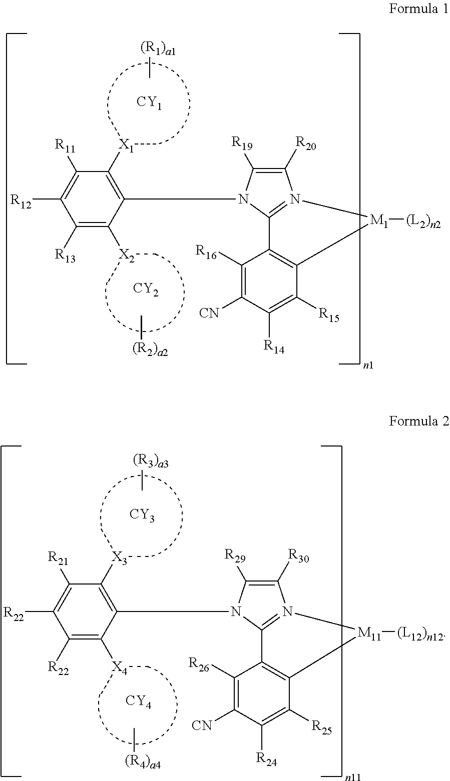

In Formulae 1 and 2,
M₁ and M₁₁ may each independently be selected from a first-row transition metal of the Periodic Table of Elements, a second-row transition metal of the Periodic Table of Elements, and a third-row transition metal of the Periodic Table of Elements,
n1 and n11 may each independently be 1, 2, or 3,
L₂ and L₁₂ may each independently be selected from a monodentate ligand and a bidentate ligand,
n2 and n12 may each independently be 0, 1, 2, 3, or 4, wherein, when n2 is two or more, two or more groups L₂ may be identical to or different from each other, and when n12 is two or more, two or more groups L₁₂ may be identical to or different from each other,
X₁ to X₄ may each independently be carbon or nitrogen,
CY₁ to CY₄ may each independently be selected from a C₅-C₃₀ carbocyclic group and a C₂-C₃₀ heterocyclic group,
R₁, R₂, and R₁₁ to R₁₆ may each independently be selected from hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₁, R₂, R₁₁ to R₁₃, CY₁, and CY₂ may optionally be linked to form a substituted or unsubstituted C₅-C₃₀ carbocyclic group or a substituted or unsubstituted C₂-C₃₀ heterocyclic group,
a1 and a2 may each independently be an integer from 0 to 5,
R₁₉ and R₂₀ may each independently be selected from hydrogen, deuterium, a C₁-C₃₀ alkyl group, a C₁-C₃₀ alkyl group substituted with at least one deuterium, a C₆-C₆₀ aryl group, and a C₆-C₆₀ aryl group substituted with at least one selected from a C₁-C₃₀ alkyl group and deuterium,
at least one of R₁, R₂, R₁₁ to R₁₆, R₁₉, and R₂₀ may be a deuterium-containing substituent,
R₃, R₄, and R₂₁ to R₂₆ may each independently be selected from hydrogen, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₃, R₄, R₂₁ to R₂₃, CY₃, and CY₄ may optionally be linked to form a substituted or unsubstituted C₅-C₃₀ carbocyclic group or a substituted or unsubstituted C₂-C₃₀ heterocyclic group,
a3 and a4 may each independently be an integer from 0 to 5,
R₂₉ and R₃₀ may each independently be selected from hydrogen, a C₁-C₃₀ alkyl group, a C₆-C₆₀ aryl group, and a C₆-C₆₀ aryl group substituted with at least one C₁-C₃₀ alkyl group, and
R₃, R₄, R₂₁ to R₂₆, R₂₉, and R₃₀ may each be a deuterium-free substituent.

According to one or more embodiments, an organic light-emitting device includes:
a first electrode;
a second electrode; and
an organic layer disposed between the first electrode and the second electrode,
wherein the organic layer includes an emission layer, and
wherein the organic layer includes at least one organometallic compound or includes the composition containing the organometallic compound.

The organometallic compound may act as a dopant in the organic layer.

### BRIEF DESCRIPTION OF THE DRAWINGS

These and/or other aspects will become apparent and more readily appreciated from the following description of the embodiments, taken in conjunction with the accompanying drawings in which:

FIG. 1 is a view for describing a process of evaluating Area_{free} in Equation 1;

FIG. 2 is a view for describing a process of evaluating Area_{screened} in Equation 1;

FIG. 3 is a view of a sphere tessellation used to derive a plane B used to evaluate Area_{screened} in Equation 1; and

FIG. 4 is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10%, 5% of the stated value.

In an embodiment, an organometallic compound is provided. The organometallic compound according to an embodiment may be represented by Formula 1 below:

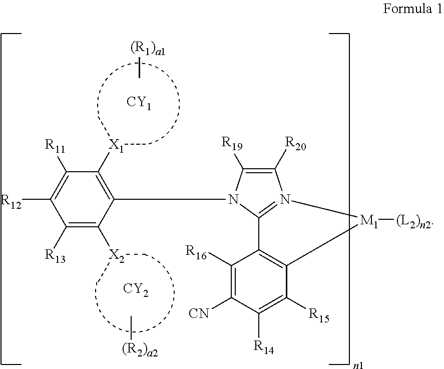

M₁ in Formula 1 may be selected from a first-row transition metal of the Periodic Table of Elements, a second-row transition metal of the Periodic Table of Elements, and a third-row transition metal of the Periodic Table of Elements.

For example, M₁ may be selected from iridium (Ir), platinum (Pt), osmium (Os), titanium (Ti), zirconium (Zr), hafnium (Hf), europium (Eu), terbium (Tb), thulium (Tm), and rhodium (Rh).

In one or more embodiments, M₁ may be iridium, but embodiments of the present disclosure are not limited thereto.

In Formula 1, n1 may be 1, 2, or 3, wherein, when n1 is two or more, two or more ligands represented by

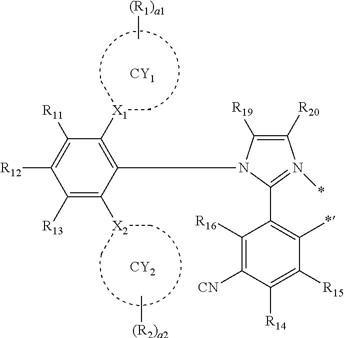

in Formula 1 (wherein * and *′ each indicate a binding site to M₁ in Formula 1) may be identical to or different from each other, L₂ may be selected from a monodentate ligand and a bidentate ligand, and n2 may be 0, 1, 2, 3, or 4, wherein, when n2 is two or more, two or more groups L₂ may be identical to or different from each other. L₂ is the same as described below.

In one or more embodiments, in Formula 1, M₁ may be Ir or Os, and the sum of n1 and n2 may be 3 or 4; or M₁ may be Pt, and the sum of n1 and n2 may be 2.

In one or more embodiments, in Formula 1, M₁ may be Ir, n1 may be 3, and n2 may be 0, but embodiments of the present disclosure are not limited thereto.

In one or more embodiments, in Formula 1, M₁ may be Ir, n1 may be 3, n2 may be 0, and three ligands represented by

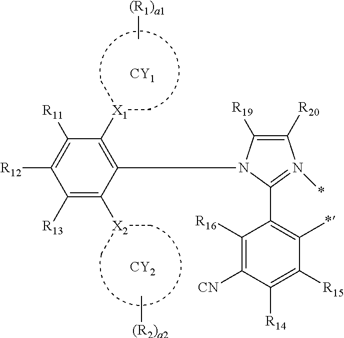

may be identical to one another.

X₁ and X₂ in Formula 1 may each independently be carbon or nitrogen.

In one or more embodiments, X₁ and X₂ may each be carbon, but embodiments of the present disclosure are not limited thereto.

CY₁ and CY₂ in Formula 1 may each independently be selected from a C₅-C₃₀ carbocyclic group and a C₂-C₃₀ heterocyclic group.

For example, CY₁ and CY₂ may each independently be selected from a cyclopentene group, a cyclohexene group, a benzene group, a pyridine group, a pyrimidine group, a pyridazine group, a pyrazine group, a triazine group, a pyrrole group, a pyrazole group, an imidazole group, a triazole group, an oxazole group, an isoxazole group, an oxadiazole group, a thiazole group, an isothiazole group, and a thiadiazole group.

In one or more embodiments, CY₁ and CY₂ may each independently be a benzene group, a pyridine group, or a pyrimidine group.

In one or more embodiments, CY₁ and CY₂ may each be a benzene group, but embodiments of the present disclosure are not limited thereto.

R₁, R₂, and R₁₁ to R₁₆ in Formula 1 may each independently be selected from hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉). Q₁ to Q₀₉ are the same as described herein.

For example, R₁, R₂, and R₁₁ to R₁₆ may each independently be selected from: hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, and a C₁-C₂₀ alkoxy group;
a C₁-C₂₀ alkyl group and a C₁-C₂₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, and a pyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, and an imidazopyrimidinyl group; and
—N(Q₁)(Q₂), —Si(Q₃)(Q₄)(Q₅), —B(Q₆)(Q₇), and —P(═O)(Q₈)(Q₉),
wherein Q₁ to Q₉ may each independently be selected from:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂;
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group; and
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group, each substituted with at least one selected from deuterium, a C₁-C₁₀ alkyl group, and a phenyl group,
but embodiments of the present disclosure are not limited thereto.

In one or more embodiments, R₁, R₂, and R₁₁ to R₁₆ may each independently be selected from:
hydrogen, deuterium, —F, a cyano group, a nitro group, —SF₅, a methyl group, an ethyl group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group;
a methyl group, an ethyl group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group, each substituted with at least one selected from deuterium, —F, —CD₃, —CD₂H, —CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group; and
—N(Q₁)(Q₂), —Si(Q₃)(Q₄)(Q₅), —B(Q₆)(Q₇), and —P(═O)(Q₈)(Q₉),
wherein Q₁ to Q₉ are the same as described herein.

Two or more neighboring groups of R₁, R₂, R₁₁ to R₁₃, CY₁, and CY₂ in Formula 1 may optionally be linked to form a C₅-C₃₀ carbocyclic group unsubstituted or substituted with at least one R₁₀₁ (for example, a 5-membered or 6-membered carbocyclic group unsubstituted or substituted with at least one R₁₀₁), or a C₂-C₃₀ heterocyclic group unsubstituted or substituted with at least one R₁₀₁ (for example, a 5-membered or 6-membered heterocyclic group unsubstituted or substituted with at least one R₁₀₁). R₁₀₁ is the same as described in connection with R₁.

a1 and a2 in Formula 1 respectively indicate the number of groups R₁ and the number of groups R₂ and may each independently be an integer from 0 to 5.

For example, a1 and a2 may each independently be 0, 1, or 2, but embodiments of the present disclosure are not limited thereto.

R₁₉ and R₂₀ in Formula 1 may each independently be selected from hydrogen, deuterium, a C₁-C₃₀ alkyl group, a C₁-C₃₀ alkyl group substituted with at least one deuterium, a C₆-C₆₀ aryl group, and a C₆-C₆₀ aryl group substituted with at least one selected from a C₁-C₃₀ alkyl group and deuterium.

In one or more embodiments, R₁, R₂, R₁₁ to R₁₆, R₁₉, and R₂₀ in Formula 1 may each independently be selected from:
hydrogen, deuterium, —CH₃, —CD₃, —CD₂H, —CDH₂, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, a phenyl group, and a group represented by one of Formulae 9-1 to 9-24; and
a phenyl group substituted with at least one selected from deuterium, —CD₃, —CD₂H, —CDH₂, and a C₁-C₁₀ alkyl group,
but embodiments of the present disclosure are not limited thereto:

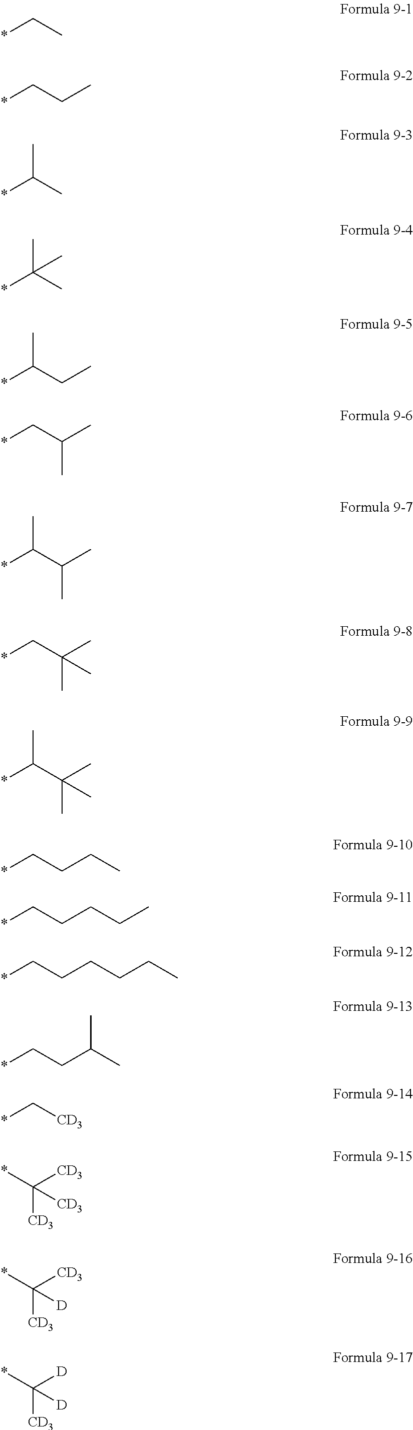

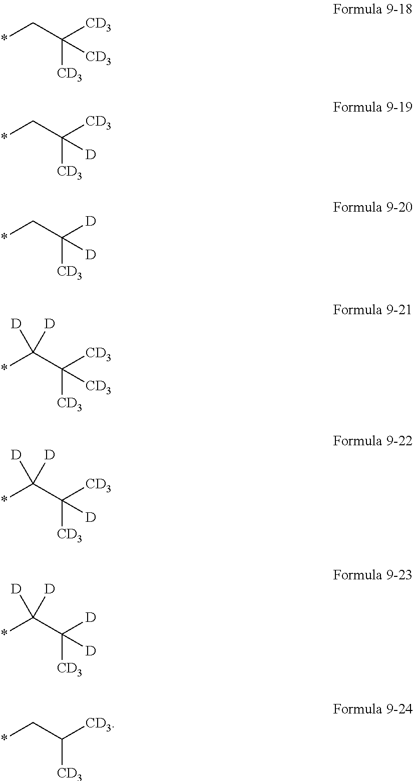

wherein, * in Formulae 9-1 to 9-24 indicates a binding site to a neighboring atom.

In one or more embodiments, at least one of R₁, R₂, R₁₁ to R₁₆, R₁₉, and R₂₀ in Formula 1 may be a deuterium-containing substituent, and the deuterium-containing substituent may be selected from:
deuterium; and
a C₁-C₂₀ alkyl group and a phenyl group, each substituted with at least one deuterium.

For example, the deuterium-containing substituent may be selected from:
deuterium; and
a methyl group, an ethyl group, an n-propyl group, an iso-propyl group, an n-butyl group, a sec-butyl group, an iso-butyl group, a tert-butyl group, an n-pentyl group, an iso-pentyl group, a 1-methylbutyl group, a 2-methylbutyl group, a neo-pentyl group, a 1,2-dimethylpropyl group, a tert-pentyl group, and a phenyl group, each substituted with at least one deuterium.

In one or more embodiments, the deuterium-containing substituent may be selected from:
deuterium; and
a methyl group, an ethyl group, an n-propyl group, an iso-propyl group, an n-butyl group, a sec-butyl group, an iso-butyl group, and a tert-butyl group, each substituted with deuterium, but embodiments of the present disclosure are not limited thereto.

In one or more embodiments, the deuterium-containing substituent may be selected from —D, —CH₂D, —CHD₂, —CD₃, —CH₂CH₂D, —CH₂CHD₂, —CH₂CD₃, —CHDCH₃, —CHDCH₂D, —CHDCHD₂, —CHDCD₃, —CD₂CH₃, —CD₂CH₂D, —CD₂CHD₂, —CD₂CD₃, —CH₂CH₂CH₂D, —CH₂CH₂CHD₂, —CH₂CH₂CD₃, —CH₂CHDCH₃, —CH₂CHDCH₂D, —CH₂CHDCHD₂, —CH₂CHDCD₃, —CH₂CD₂CH₃, —CH₂CD₂CH₂D, —CH₂CD₂CHD₂, —CH₂CD₂CD₃, —CHDCH₂CH₂D, —CHDCH₂CHD₂, —CHDCH₂CD₃, —CHDCHDCH₃, —CHDCHDCH₂D, —CHDCHDCHD₂, —CHDCHDCD₃, —CHDCD₂CH₃, —CHDCD₂CH₂D, —CHDCD₂CHD₂, —CHDCD₂CD₃, —CD₂CH₂CH₂D, —CD₂CH₂CHD₂, —CD₂CH₂CD₃, —CD₂CHDCH₃, —CD₂CHDCH₂D, —CD₂CHDCHD₂, —CD₂CHDCD₃, —CD₂CD₂CH₃, —CD₂CD₂CH₂D, —CD₂CD₂CHD₂, —CD₂CD₂CD₃, —CH(CH₃)(CH₂D), —CH(CH₃)(CHD₂), —CH(CH₂D)(CH₂D), —CH(CH₃)(CD₃), —CH(CHD₂)(CHD₂), —CH(CH₂D)(CD₃), CH(CHD₂)(CHD₂), —CH(CHD₂)(CD₃), —CH(CD₃)₂, —CD(CH₃)₂, —CD(CH₃)(CH₂D), —CD(CH₃)(CHD₂), —CD(CH₂D)(CH₂D), —CD(CH₃)(CD₃), —CD(CHD₂)(CHD₂), CD(CH₂D)(CD₃), —CD(CHD₂)(CHD₂), —CD(CHD₂)(CD₃), —CD(CD₃)₂, and —C(CD₃)₃, but embodiments of the present disclosure are not limited thereto.

In one or more embodiments, the deuterium-containing substituent may be selected from deuterium, —CD₃, —CD₂H, —CDH₂, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, and groups represented by Formulae 9-14 to 9-24, but embodiments of the present disclosure are not limited thereto.

In one or more embodiments, the ligand represented by

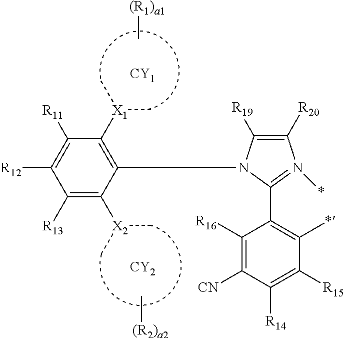

in Formula 1 (wherein * and *′ each indicate a binding site to M₁ in Formula 1) may include at least one deuterium. Whether the ligand represented by

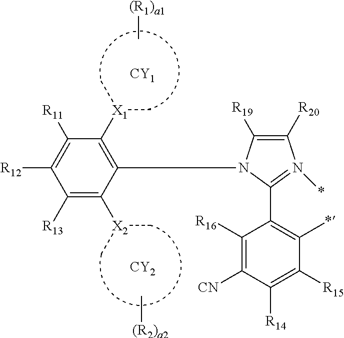

includes deuterium may be confirmed by analyzing the organometallic compound represented by Formula 1 through a ¹H NMR spectrum or analyzing a molecular weight of the organometallic compound by using a molecular weight measurement apparatus such as matrix-assisted laser desorption/ionization (MALDI) apparatus.

A compound (hereinafter, referred to as a “first standard compound”), which has the same backbone as the organometallic compound represented by Formula 1 but does not include deuterium, is prepared. A ¹H NMR spectrum of the first standard compound and a ¹H NMR spectrum of the organometallic compound represented by Formula 1 are obtained. Then, the number of hydrogens that are substituted with deuterium among hydrogens bonded at a specific position (specific carbon) of the organometallic compound represented by Formula 1 may be calculated by comparing integral values of signals of specific ppm selected from the measured spectrum.

In one or more embodiments, a compound (hereinafter, referred to as a “second standard compound”) which has the same backbone as the organometallic compound represented by Formula 1 and in which all hydrogens of the organometallic compound represented by Formula 1 are substituted with deuterium is assumed. The number of hydrogens of the organometallic compound represented by Formula 1 that are substituted with deuterium may be calculated by comparing a calculated molecular weight of the second standard compound with a molecular weight of the organometallic compound represented by Formula 1.

In one or more embodiments, at least one of R₁₂, R₁₄, R₁₉, and R₂₀ in Formula 1 may be a deuterium-containing substituent as described above. The deuterium-containing substituent is the same as described herein.

In one or more embodiments, at least one of R₁₁, R₁₂, R₁₃, R₁₉, and R₂₀ in Formula 1 (for example, all of R₁₁, R₁₂, R₁₃, R₁₉, and R₂₀) may a deuterium-containing substituent as described above. The deuterium-containing substituent is the same as described herein.

In one or more embodiments, R₁₂ and R₁₄ in Formula 1 may each independently be selected from:
hydrogen, deuterium, —CH₃, —CD₃, —CD₂H, —CDH₂, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, a phenyl group, and groups represented by Formulae 9-1 to 9-24; and
a phenyl group substituted with at least one selected from deuterium, —CD₃, —CD₂H, —CDH₂, and a C₁-C₁₀ alkyl group, and
R₁₉ and R₂₀ may each independently be hydrogen or deuterium, but embodiments of the present disclosure are not limited thereto.

The organometallic compound represented by Formula 1 may be represented by Formula 1-1:

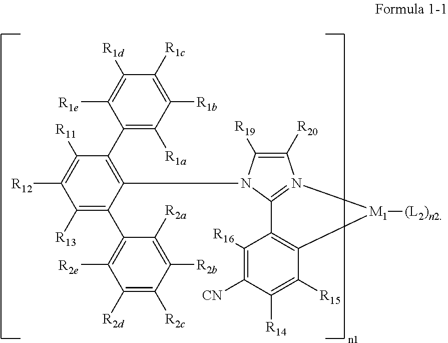

In Formula 1-1, M₁, n1, L₂, n2, R₁₁ to R₁₆, R₁₉, and R₂₀ are the same as described herein, R₁ₐ to R₁ₑ are the same as described in connection with R₁, and R₂ₐ to R₂ₑ are the same as described in connection with R₂.

For example, at least one of R₁₁ to R₁₃ in Formula 1-1 may each independently be a deuterium-containing substituent as described herein.

In one or more embodiments, in Formula 1-1, at least one of R₁₁ to R₁₃, at least one of R₁ₐ to R₁ₑ, and at least one of R₂ₐ to R₂ₑ may each independently be a deuterium-containing substituent as described herein.

In one or more embodiments, R₁₁ to R₁₃, R₁ₐ to R₁ₑ, and R₂ₐ to R₂ₑ in Formula 1-1 may each independently be a deuterium-containing substituent as described herein, but embodiments of the present disclosure are not limited thereto.

In one or more embodiments, the organometallic compound represented by Formula 1 may be represented by Formula 1(1):

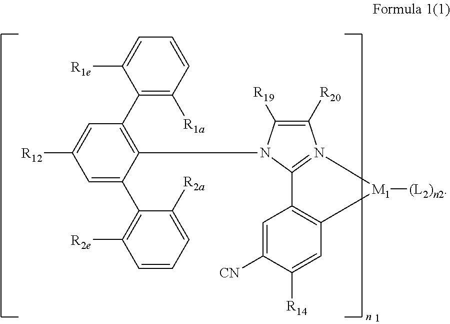

In Formula 1(1), M₁, n1, L₂, n2, R₁₂, R₁₄, R₁₉, and R₂₀ are the same as described herein, R₁ₐ and R₁ₑ are the same as described in connection with R₁, and R₂ₐ and R₂ₑ are the same as described in connection with R₂.

In one or more embodiments, at least one of R₁ₐ, R₁ₑ, R₂ₐ, R₂ₑ, R₁₂, R₁₄, R₁₉, and R₂₀ in Formulae 1-1 and 1(1) may not be hydrogen.

For example, at least one of R₁ₐ, R₁ₑ, R₂ₐ, R₂ₑ, R₁₂, R₁₄, R₁₉, and R₂₀ in Formulae 1-1 and 1(1) may each independently be selected from:
deuterium, —CH₃, —CD₃, —CD₂H, —CDH₂, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, a phenyl group, and groups represented by Formulae 9-1 to 9-24; and
a phenyl group substituted with at least one selected from deuterium, —CD₃, —CD₂H, —CDH₂, and a C₁-C₁₀ alkyl group,
but embodiments of the present disclosure are not limited thereto.

In one or more embodiments, at least one of R₁₄, R₁₉, and R₂₀ in Formulae 1-1 and 1(1) may be a deuterium-containing substituent. The deuterium-containing substituent are the same as described herein.

In one or more embodiments, at least one of R₁₉ and R₂₀ in Formulae 1-1 and 1(1) may be deuterium.

L₂ in Formula 1 may be selected from a monodentate ligand and a bidentate ligand.

For example, in Formula 1, L₂ may be a monodentate ligand, and L₂ may be selected from I⁻, Br⁻, Cl⁻, sulfide, nitrate, azide, hydroxide, cyanate, isocyanate, thiocyanate, water, acetonitrile, pyridine, ammonia, carbon monoxide, P(Ph)₃, P(Ph)₂CH₃, PPh(CH₃)₂, and P(CH₃)₃, but embodiments of the present disclosure are not limited thereto.

In one or more embodiments, in Formula 1, L₂ may be a bidentate ligand, and L₂ may be selected from oxalate, acetylacetonate, a picolinic acid, 1,2-bis(diphenylphosphino)ethane, 1,1-bis(diphenylphosphino)methane, glycinate, and ethylenediamine, but embodiments of the present disclosure are not limited thereto.

In one or more embodiments, L₂ in Formula 1 may be selected from ligands represented by Formulae 3A to 3F:

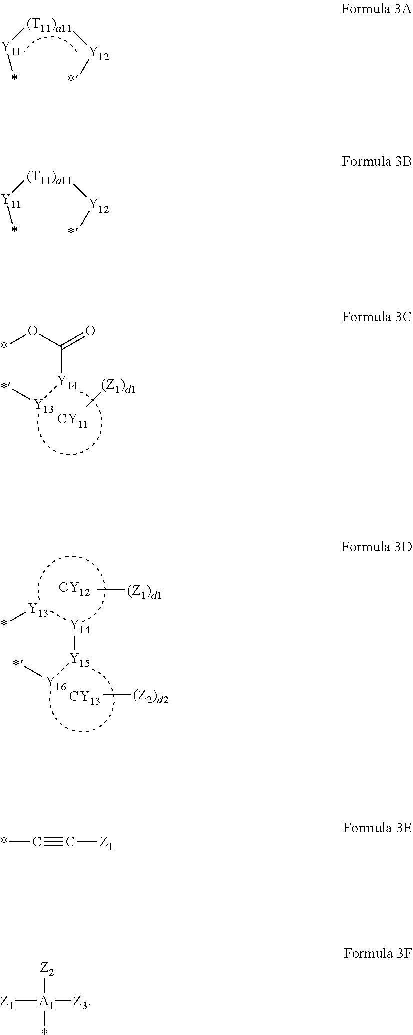

In Formulae 3A to 3F,
Y₁₁ may be selected from O, N, N(Z₁), P(Z₁)(Z₂), and As(Z₁)(Z₂),
Y₁₂ may be selected from O, N, N(Z₃), P(Z₃)(Z₄), and As(Z₃)(Z₄),
CY₁₁ may be a C₂-C₃₀ heterocyclic group (for example, a pyridine group, a pyrimidine group, a quinoline group, an isoquinoline group, a quinoxaline group, a carbazole group, or the like),
T₁₁ may each independently be selected from a single bond, a double bond, *—C(Z₁₁)(Z₁₂)—*′, *—C(Z₁₁)═C(Z₁₂)—*′, *═C(Z₁₁)—*′, *—C(Z₁₁)═*′, *═C(Z₁₁)—C(Z₁₂)═C(Z₁₃)*′, *—C(Z₁₁)═C(Z₁₂)—C(Z₁₃)═*′, *—N(Z₁₁)—*′, and a substituted or unsubstituted C₅-C₃₀ carbocyclic group,
all may be an integer from 1 to 10,
Y₁₃ to Y₁₆ may each independently be carbon (C) or nitrogen (N), wherein Y₁₃ and Y₁₄ may be linked via a single bond or a double bond, and Y₁₅ and Y₁₆ are linked via a single bond or a double bond,
CY₁₂ and CY₁₃ may each independently be selected from a C₅-C₃₀ carbocyclic group and a C₂-C₃₀ heterocyclic group (for example, a benzene group, a naphthalene group, a fluorene group, a dibenzofuran group, a dibenzothiophene group, a pyrazole group, an imidazole group, a triazole group, a tetrazole group, a pyridine group, a pyrimidine group, a quinoline group, an isoquinoline group, a quinoxaline group, a carbazole group, or the like),
A₁ may be P or As,
Z₁ to Z₄ and Z₁₁ to Z₁₃ may each independently be selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
d1 and d2 may each independently be an integer from 0 to 10, and
* and *′ each indicate a binding site to M in Formula 1.

In one or more embodiments, L₂ in Formula 1 may be represented by one of Formulae 5-1 to 5-119, but embodiments of the present disclosure are not limited thereto:

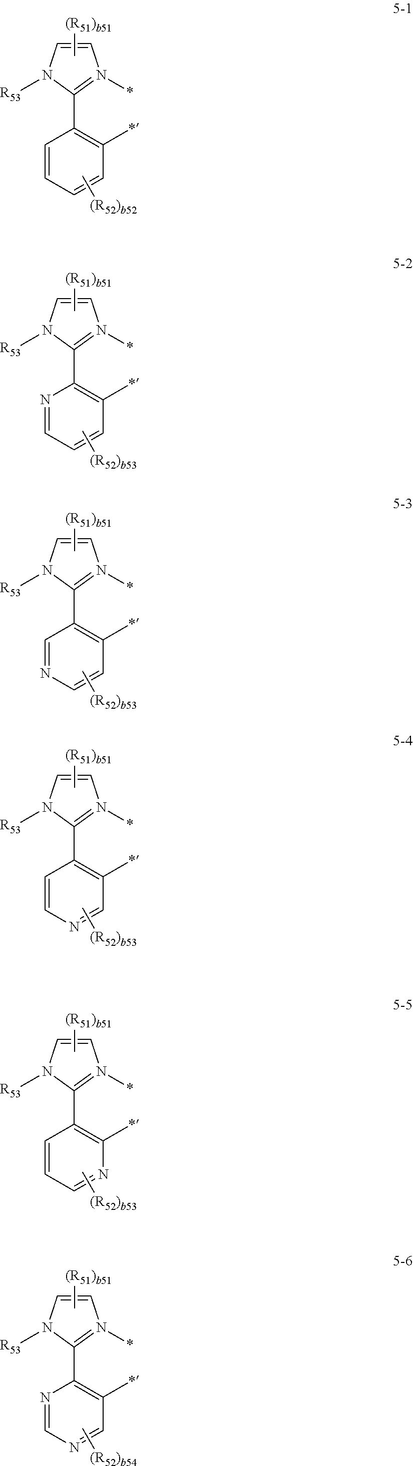

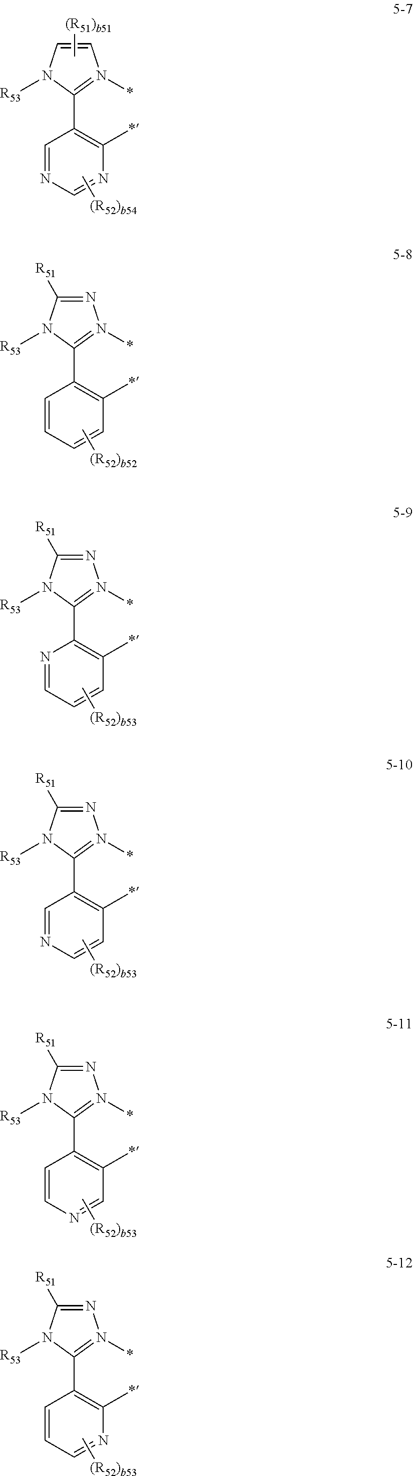

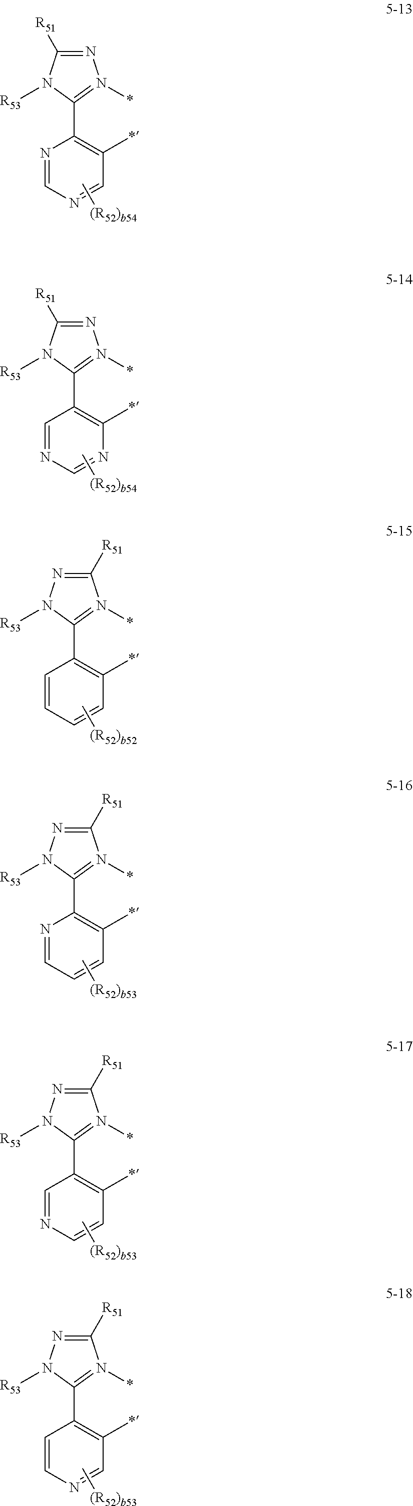

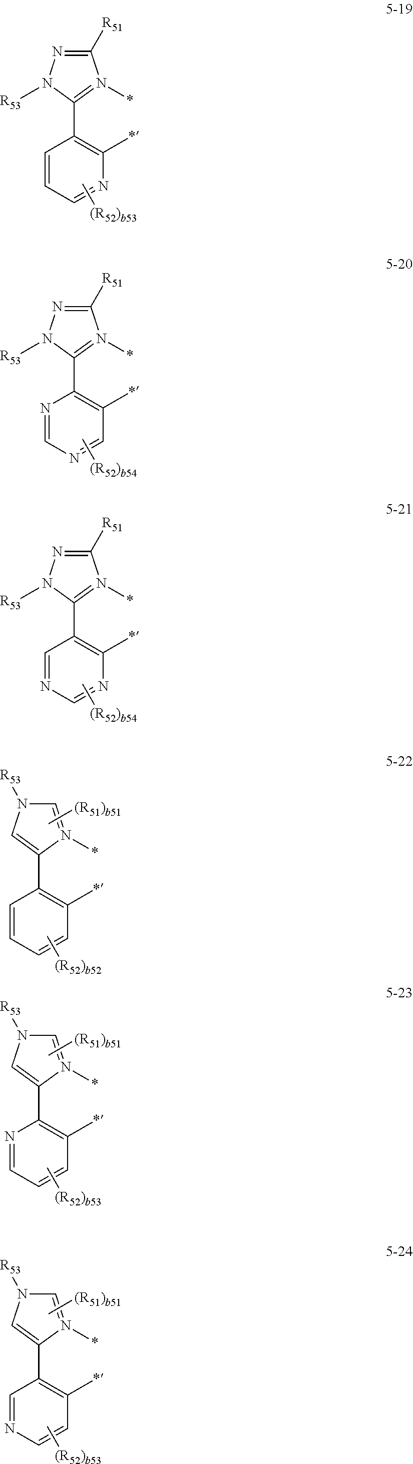

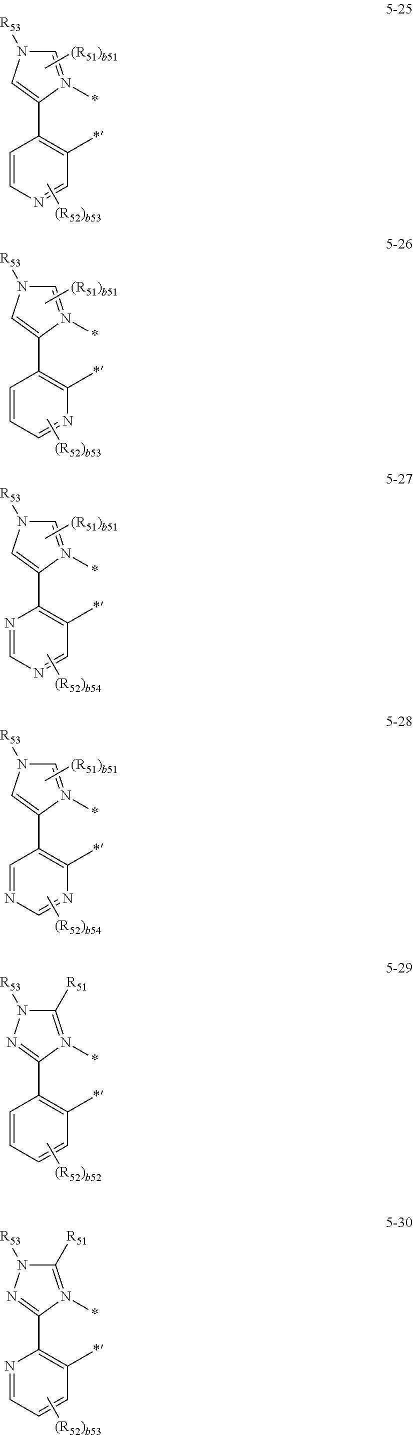

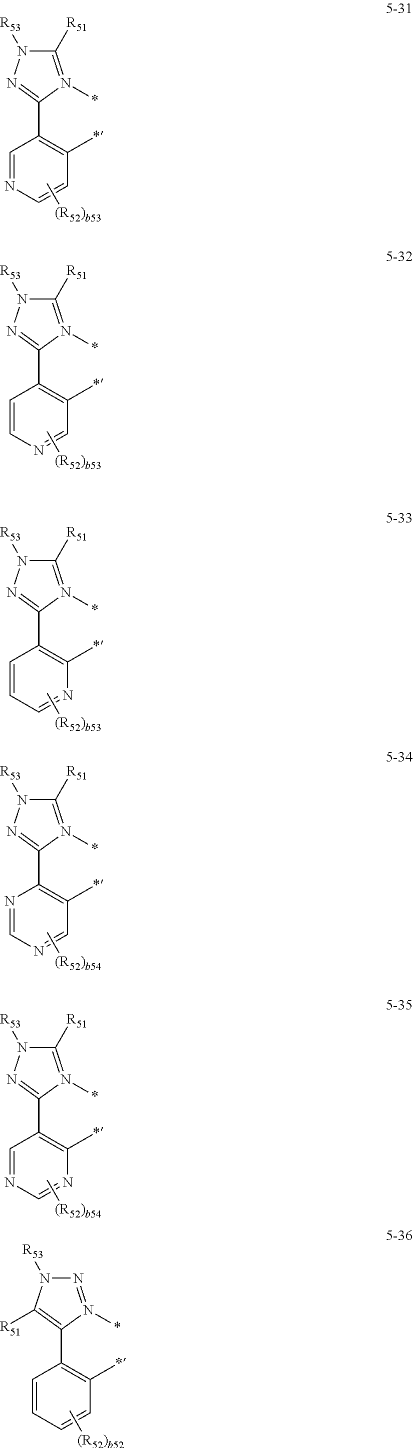

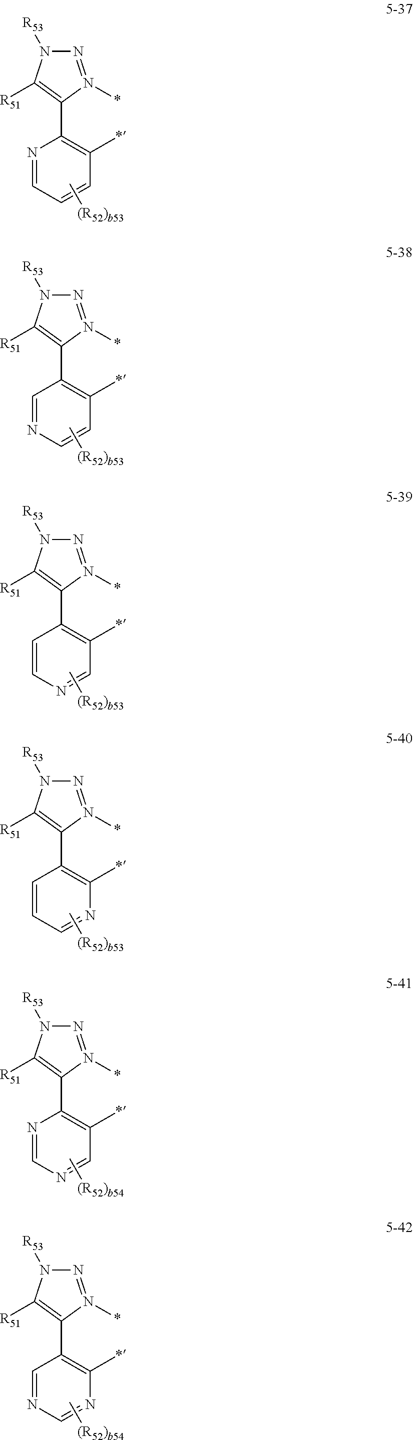

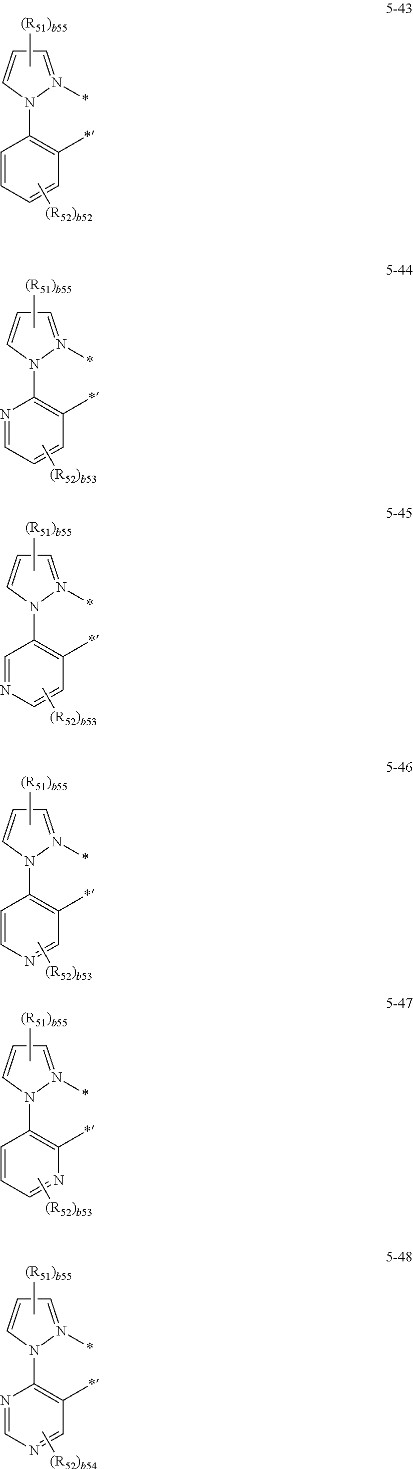

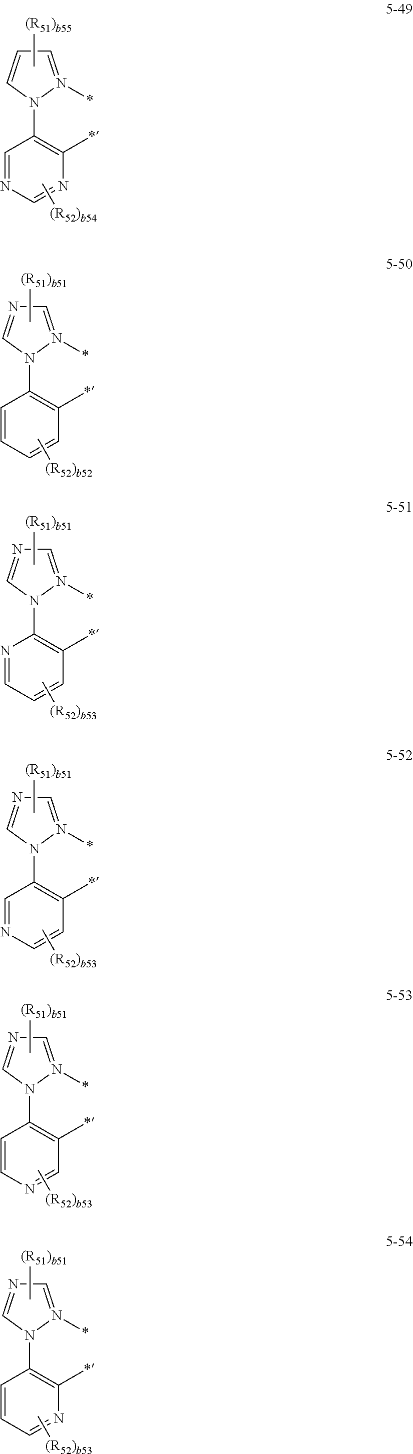

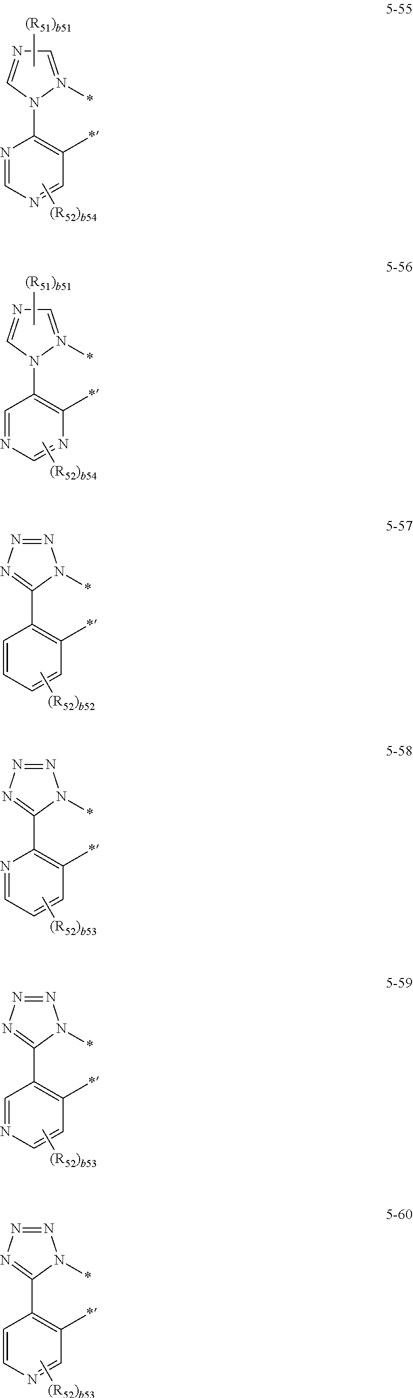

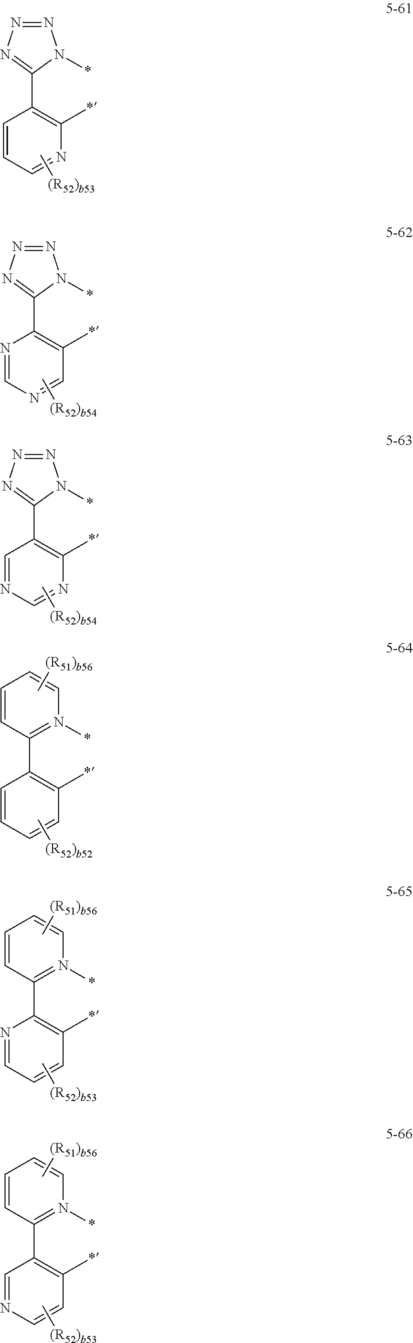

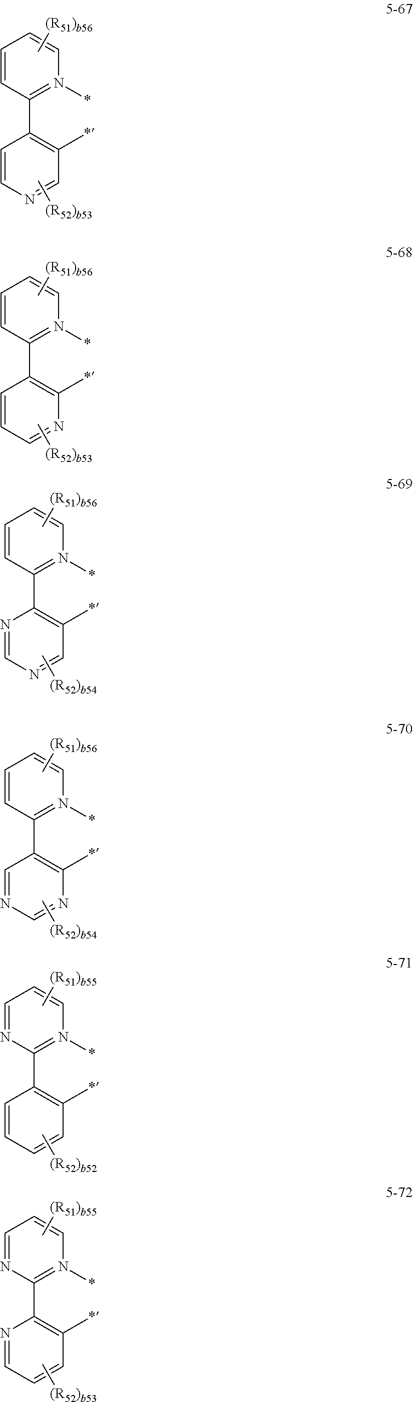

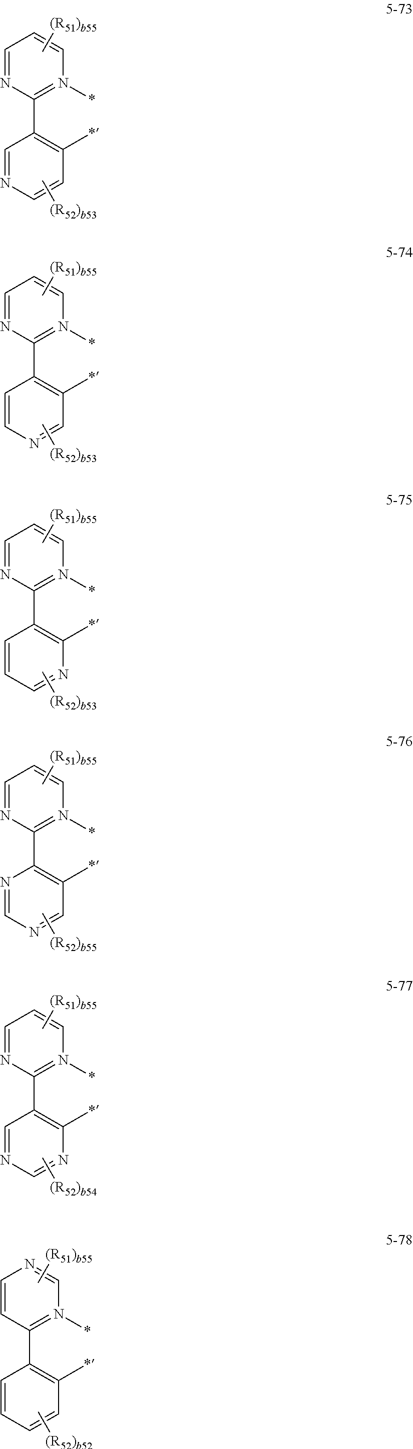

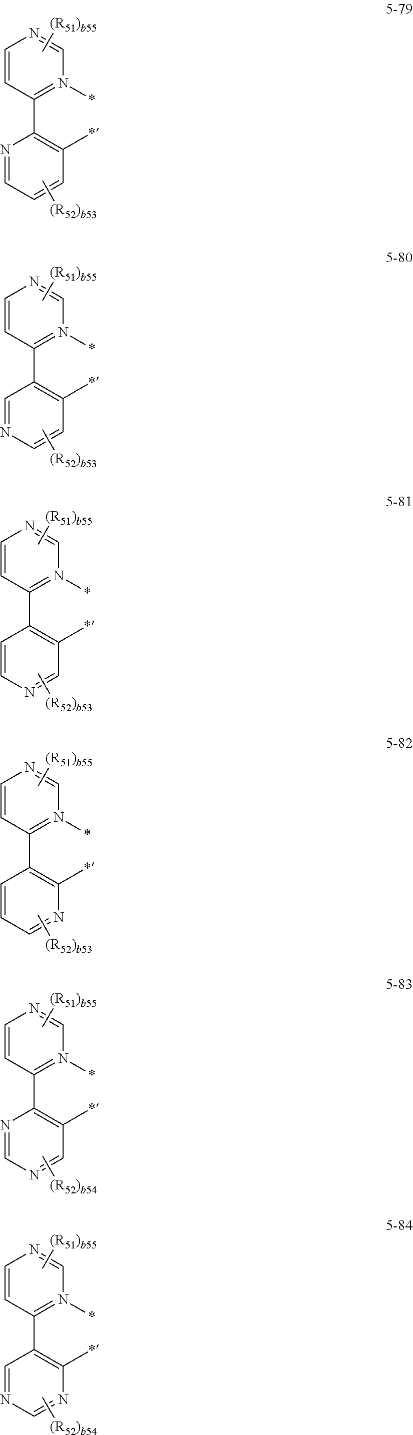

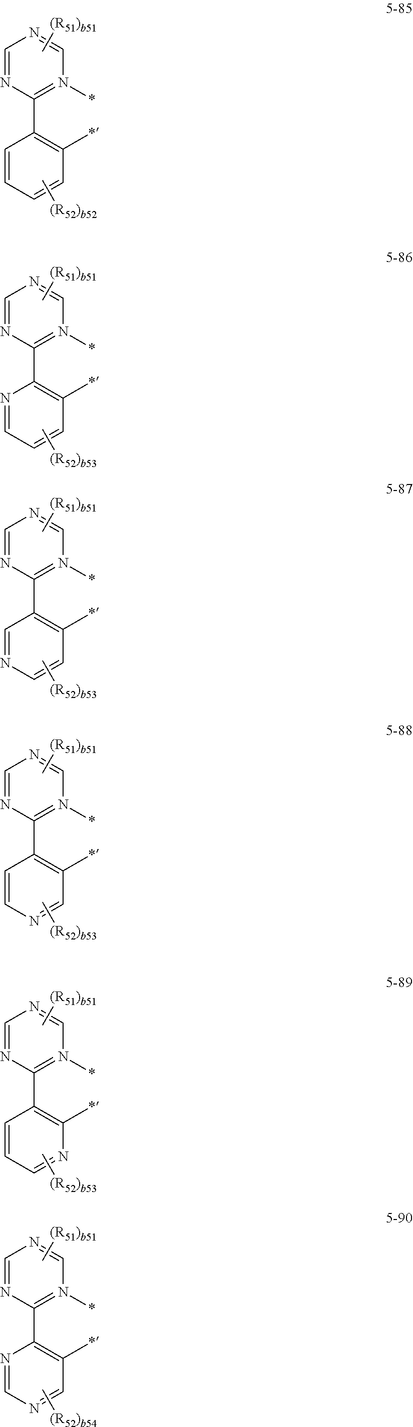

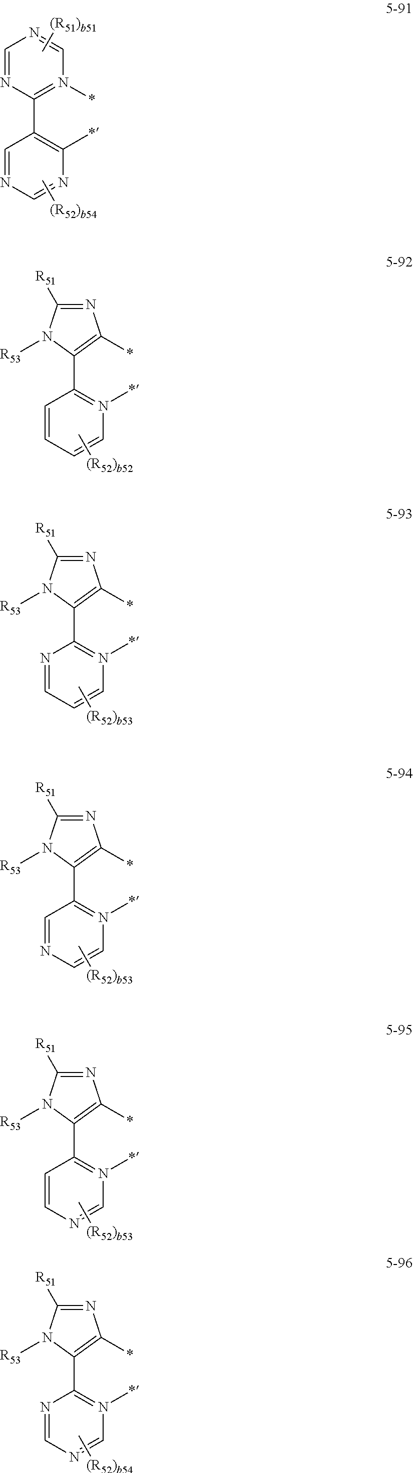

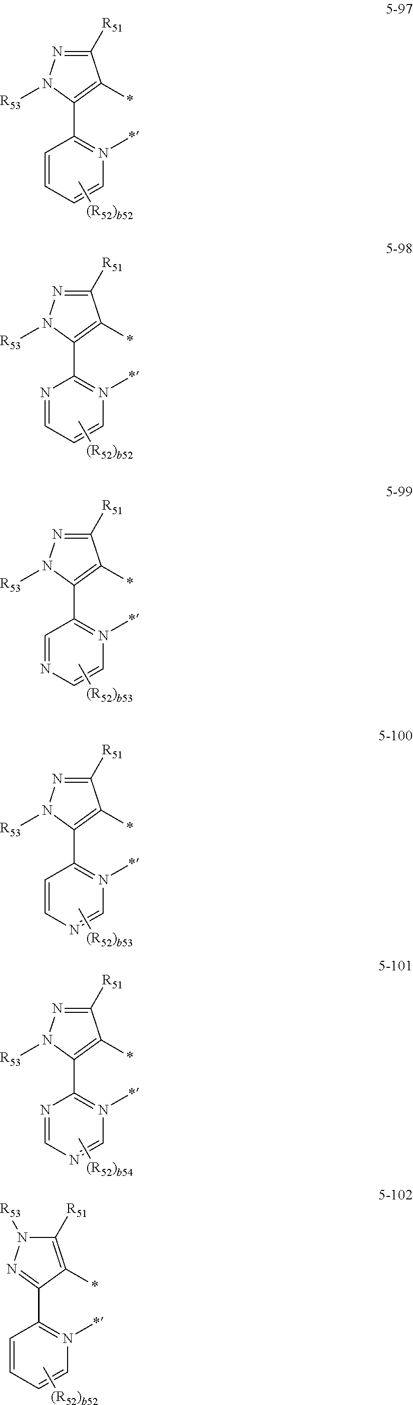

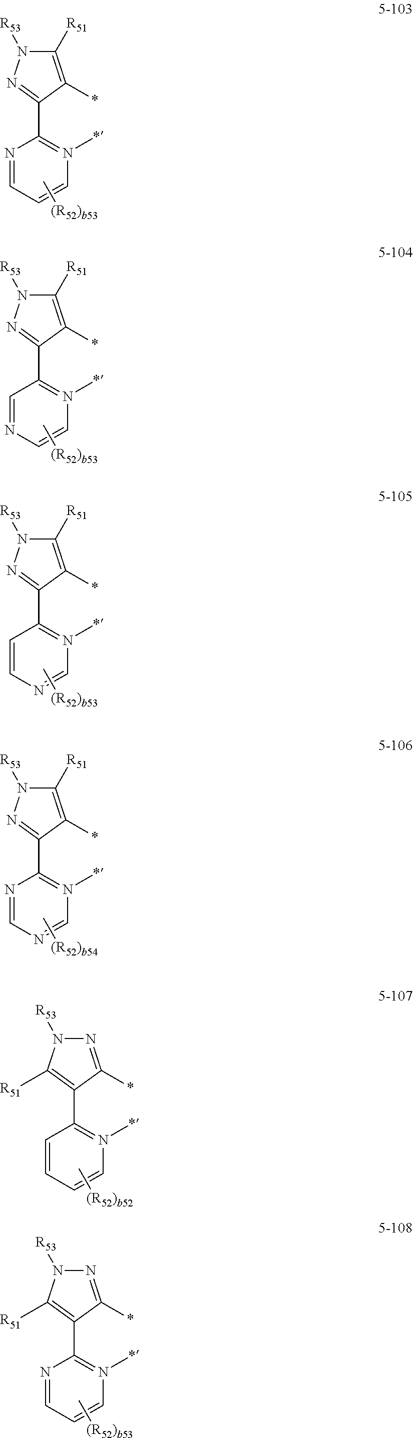

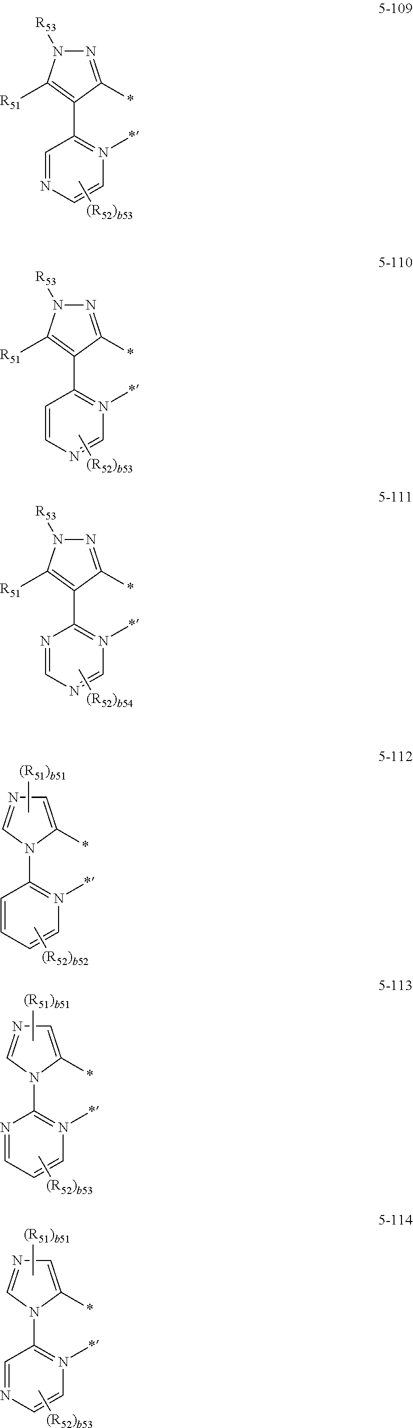

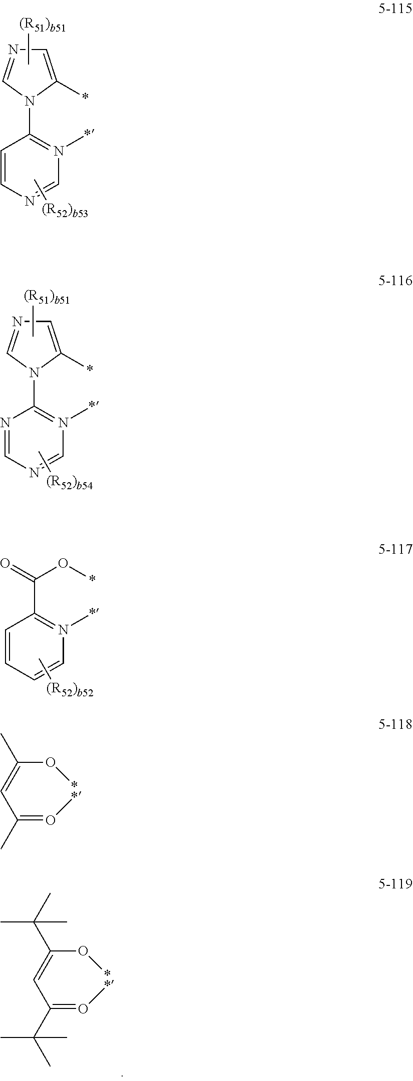

In Formulae 5-1 to 5-119,
R₅₁ to R₅₃ may each independently be selected from:
hydrogen, —F, a cyano group, a nitro group, a methyl group, an ethyl group, a propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decanyl group, an iso-decanyl group, a sec-decanyl group, a tert-decanyl group, a methoxy group, an ethoxy group, a propoxy group, a butoxy group, a pentoxy group, a phenyl group, a naphthyl group, a pyridinyl group, a pyrimidinyl group, a triazinyl group, a dibenzofuranyl group, and a dibenzothiophenyl group; and
a methyl group, an ethyl group, a propyl group, an n-butyl group, an iso-butyl group, a sec-butyl group, a tert-butyl group, an n-pentyl group, an iso-pentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decanyl group, an iso-decanyl group, a sec-decanyl group, a tert-decanyl group, a methoxy group, an ethoxy group, a propoxy group, a butoxy group, a pentoxy group, a phenyl group, a naphthyl group, a pyridinyl group, a pyrimidinyl group, a triazinyl group, a dibenzofuranyl group, and a dibenzothiophenyl group, each substituted with at least one selected from —F, a cyano group, and a nitro group,
b51 and b54 may each independently be 1 or 2,
b53 and b55 may each independently be an integer from 1 to 3,
b52 may be an integer from 1 to 4, and
* and *′ each indicate a binding site to M₁ in Formula 1.

The organometallic compound represented by Formula 1 is neutral and may not have a salt form including an anion and a cation.

The organometallic compound represented by Formula 1 may be selected from Compounds 1 to 9, but embodiments of the present disclosure are not limited thereto:

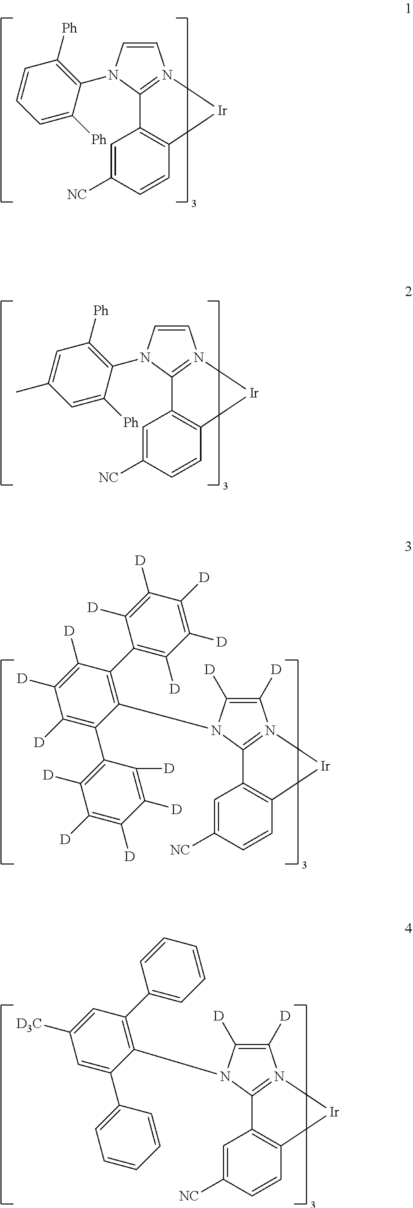

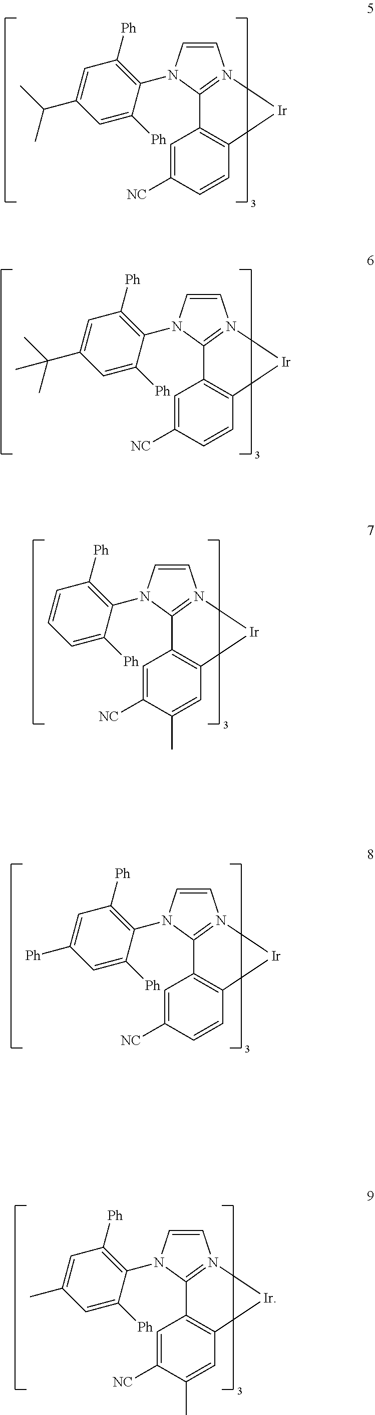

wherein “Ph” in Compounds 1 to 9 indicates a phenyl group.

A maximum emission wavelength of the organometallic compound may be in a range of about 440 nanometers (nm) to about 470 nm (for example, about 440 nm to about 467 nm). When the maximum emission wavelength is in a range of about 440 nm to about 470 nm, an organic light-emitting device emitting deep blue light may be provided.

The organometallic compound represented by Formula 1 essentially includes CY₁ and CY₂ at positions defined herein.

Thus, the organometallic compound may have a natural population analysis (NPA) charge value of about 0.50 or less, for example, about 0 to about 0.48. The NPA charge value is evaluated by a density functional theory (DFT) method using a Gaussian program that is structurally optimized at a level of B3LYP/6-31G(d,p).

Also, an open fraction value of atom A bonded to R₁₉ in Formula 1 (see Formula 1′) may be about 0.5 or less, for example, about 0.1 to about 0.49.

Formula 1′

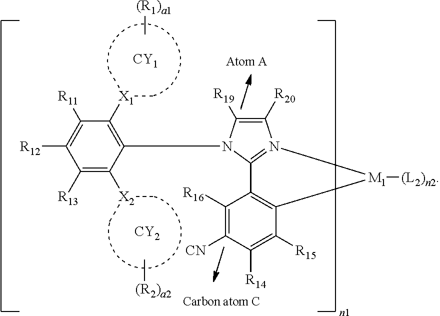

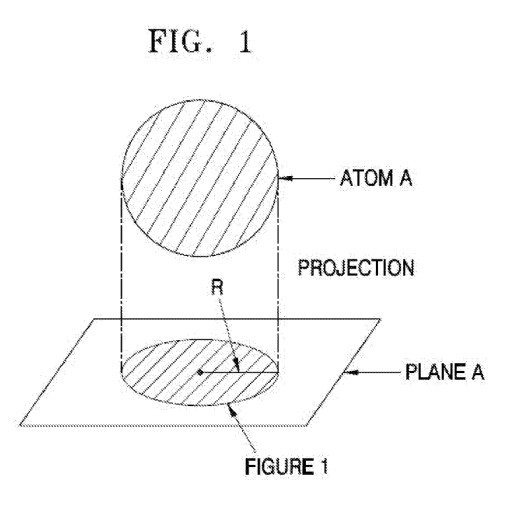

The open fraction value is calculated by using Equation 1. Equation 1 will be described below with reference to FIGS. 1 to 3:

Open fraction value=Area_{screened}/Area_{free}. Equation 1

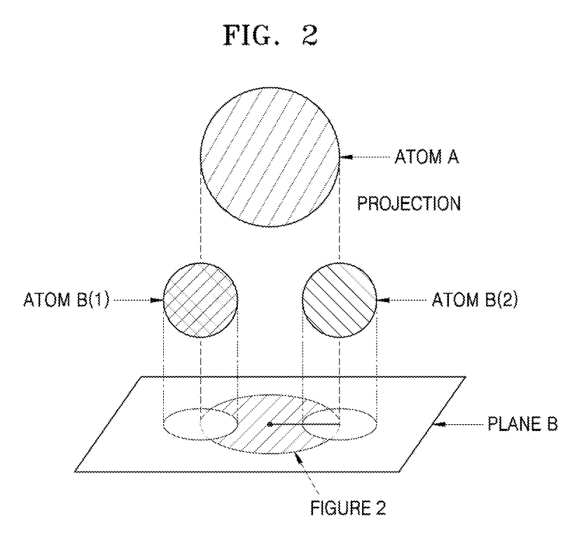

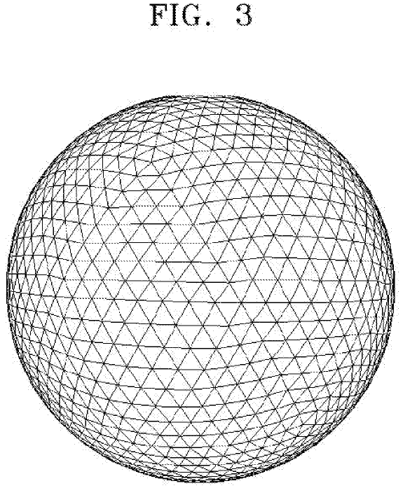

In Equation 1,
Area_{free} represents an area of a two-dimensional figure (see “FIG. 1” in FIG. 1) obtained by projecting the atom A (see “ATOM A” in FIG. 1) on a plane A (see “PLANE A” in FIG. 1) and is calculated by π×(van der Waals radius of atom A)² (wherein the van der Waals radius of the atom A (that is, van der Waals radius of a carbon atom) refers to “R” in FIG. 1),
Area_{screened} represents an average value of an area of a two-dimensional figure (see “FIG. 2” in FIG. 2) obtained by projecting the atom A (see “ATOM A” in FIG. 2) screened by another atom B of Formula 1 (see “ATOM B(1)” and “ATOM B(2)” in FIG. 2) on a plane B (see “PLANE B” in FIG. 2),
assumming that the atom A and the atom B each have a spherical shape,
the plane B is planes in which vectors directing from each of 492 points on a spherical surface of a sphere tessellation (see FIG. 3) toward the origin of the sphere tessellation are normal vectors, and
the Area_{screened} is calculated by a DFT method using a Gaussian program that is structurally optimized at a level of B3LYP/6-31G(d,p).

The atom B means a combination of any atoms that can screen the atom A of Formula 1.

The open fraction value represents how much the atom A is opened in Formula 1. As the open fraction value decreases, the atom A is more screened by another atom B in Formula 1 and is less opened. A bond between the atom A and R₁₉ in Formula 1 is a relatively weak bond that may be easily damaged by heat or the like generated when an organic light-emitting device is stored and/or driven. Since the atom A of Formula 1 has a relatively small open fraction value as described above, that is, since a relatively large portion of the atom A is screened by another atom B of Formula 1, damage to the bond between the atom A and R₁₉ in Formula 1 may be substantially prevented. Thus, the organometallic compound represented by Formula 1 may have robustness.

Since the organometallic compound having the NPA charge value and the open fraction value in the above-described ranges has excellent heat resistance and/or decomposition resistance, an electronic device (for example, an organic light-emitting device) including the organometallic compound may have a long lifespan.

On the other hand, a “carbon atom C” in Formula 1 is essentially bonded to a cyano group (see Formula 1′). Thus, since the organometallic compound represented by Formula 1 has a deep highest occupied molecular orbital (HOMO) energy level (that is, a large absolute value of a HOMO energy level or a low HOMO energy level), the organometallic compound may have a high triplet energy level. Therefore, the use of the organometallic compound represented by Formula 1 may make it possible to emit deep blue light having excellent color purity.

Also, in one or more embodiments, the organometallic compound represented by Formula 1 may include at least one deuterium. For example, at least one of R₁₉ and R₂₀ in Formula 1 may be a deuterium-containing substituent. Compared with a single bond between carbon and hydrogen, a single bond between carbon and deuterium has a strong bond strength and a short bond length. Thus, the deuterium-containing organometallic compound may have higher thermal stability than the deuterium-free organometallic compound. Therefore, radicalization of the organometallic compound represented by Formula 1 slowly progresses due to heat and/or electric field generated when the organic light-emitting device is kept and/or driven, and thus, an organic light-emitting device including the organometallic compound may have a longer lifespan.

Furthermore, in one or more embodiments, R₁₄ in Formula 1 may be a substituent other than hydrogen. For example, R₁₄ in Formula 1 may be a C₁-C₂₀ alkyl group or a deuterium-containing substituent. The organometallic compound represented by Formula 1 may have a high lowest unoccupied molecular orbital (LUMO) energy level and a high triplet (Ti) energy level. Thus, the use of the organometallic compound represented by Formula 1 may make it possible to emit blue light having excellent color purity.

Table 1 below shows results obtained when HOMO energy levels, LUMO energy levels, T₁ energy levels, and maximum emission wavelengths of some of the organometallic compounds represented by Formula 1 and Compounds E and F were evaluated using a Gaussian 09 program for optimizing a molecular structure through DFT based on B3LYP.

TABLE 1

| Compound | | | | |
|---|---|---|---|---|
| No. | HOMO (eV) | LUMO (eV) | T₁ (eV) | λₘₐₓ (nm) |
| 1 | −5.19 | −1.26 | 2.66 | 478 |
| 2 | −5.13 | −1.17 | 2.67 | 476 |
| 3 | −5.19 | −1.26 | 2.66 | 478 |
| 4 | −5.13 | −1.17 | 2.67 | 476 |
| 5 | −5.13 | −1.16 | 2.66 | 476 |
| 6 | −5.12 | −1.15 | 2.66 | 476 |
| 7 | −5.09 | −1.18 | 2.69 | 473 |
| 8 | −5.41 | −1.64 | 2.65 | 484 |
| 9 | −5.03 | −1.09 | 2.69 | 471 |
| E | −5.14 | −1.47 | 2.47 | 503 |
| F | −5.18 | −1.50 | 2.48 | 499 |

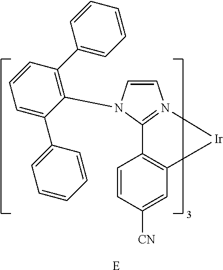

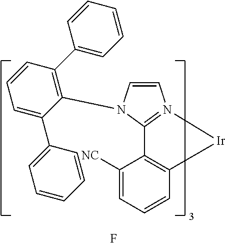

From Table 1, it can be confirmed that Compounds 1 to 9 have relatively high Ti energy levels, as compared with Compounds E and F.

On the other hand, in synthesizing an organometallic compound that is represented by Formula 1 but includes at least one deuterium, if the organometallic compound is not completely deuterated, an organometallic compound in which hydrogen is not substituted with deuterium may also be synthesized. Thus, a composition containing the organometallic compound, which includes the organometallic compound represented by Formula 1 (hereinafter, a “first organometallic compound”) and further includes an organometallic compound represented by Formula 2 (hereinafter, a “second organometallic compound”), may be provided:

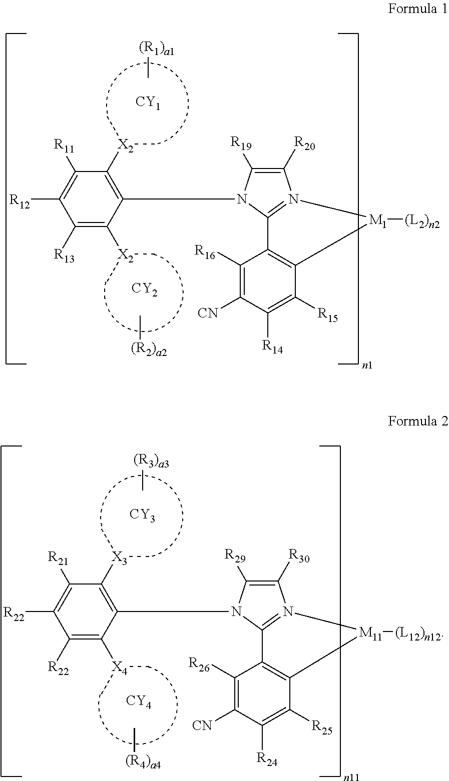

In Formulae 1 and 2,
M₁ and M₁₁ may each independently be selected from a first-row transition metal of the Periodic Table of Elements, a second-row transition metal of the Periodic Table of Elements, and a third-row transition metal of the Periodic Table of Elements,
n1 and n11 may each independently be 1, 2, or 3,
L₂ and L₁₂ may each independently be selected from a monodentate ligand and a bidentate ligand,
n2 and n12 may each independently be 0, 1, 2, 3, or 4, wherein, when n2 is two or more, two or more groups L₂ may be identical to or different from each other, and when n12 is two or more, two or more groups L₁₂ may be identical to or different from each other,
X₁ to X₄ may each independently be carbon or nitrogen,
CY₁ to CY₄ may each independently be selected from a C₅-C₃₀ carbocyclic group and a C₂-C₃₀ heterocyclic group,
R₁, R₂, and R₁₁ to R₁₆ may each independently be selected from hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₁, R₂, R₁₁ to R₁₃, CY₁, and CY₂ may optionally be linked to form a substituted or unsubstituted C₅-C₃₀ carbocyclic group or a substituted or unsubstituted C₂-C₃₀ heterocyclic group,
a1 and a2 may each independently be an integer from 0 to 5,
R₁₉ and R₂₀ may each independently be selected from hydrogen, deuterium, a C₁-C₃₀ alkyl group, a C₁-C₃₀ alkyl group substituted with at least one deuterium, a C₆-C₆₀ aryl group, and a C₆-C₆₀ aryl group substituted with at least one selected from a C₁-C₃₀ alkyl group and deuterium,
at least one of R₁, R₂, R₁₁ to R₁₆, R₁₉, and R₂₀ may be a deuterium-containing substituent,
R₃, R₄, and R₂₁ to R₂₆ may each independently be selected from hydrogen, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₃, R₄, R₂₁ to R₂₃, CY₃, and CY₄ may optionally be linked to form a substituted or unsubstituted C₅-C₃₀ carbocyclic group or a substituted or unsubstituted C₂-C₃₀ heterocyclic group,
a3 and a4 may each independently be an integer from 0 to 5,
R₂₉ and R₃₀ may each independently be selected from hydrogen, a C₁-C₃₀ alkyl group, a C₆-C₆₀ aryl group, and a C₆-C₆₀ aryl group substituted with at least one C₁-C₃₀ alkyl group, and
R₃, R₄, R₂₁ to R₂₆, R₂₉, and R₃₀ may each be a deuterium-free substituent.

Formula 1 is the same as described herein, and M₁₁, n11, L₁₂, n12, X₃, X₄, CY₃, CY₄, R₃, R₄, R₂₁ to R₂₆, a3, a4, R₂₉, and R₃₀ in Formula 2 are the same as described in connection with M₁, n1, L₂, n2, X₁, X₂, CY₁, CY₂, R₁, R₂, R₁₁ to R₁₆, a1, a2, R₁₉, and R₂₀ in Formula 1, except that deuterium is not included.

For example, in Formula 2,
M₁₁ may be Ir or Os, and the sum n11 and n12 may be 3 or 4; or M₁₁ may be Pt, and the sum of n11 and n12 may be 2,
CY₃ and CY₄ may each independently be selected from a cyclopentene group, a cyclohexene group, a benzene group, a pyridine group, a pyrimidine group, a pyridazine group, a pyrazine group, a triazine group, a pyrrole group, a pyrazole group, an imidazole group, a triazole group, an oxazole group, an isoxazole group, an oxadiazole group, a thiazole group, an isothiazole group, and a thiadiazole group,
R₃, R₄, and R₂₁ to R₂₆ may each independently be selected from:
hydrogen, —F, a cyano group, a nitro group, —SF₅, a methyl group, an ethyl group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group;
a methyl group, an ethyl group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group, each substituted with at least one selected from —F, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group; and
—N(Q₁)(Q₂), —Si(Q₃)(Q₄)(Q₅), —B(Q₆)(Q₇), and —P(═O)(Q₈)(Q₉),
a3 and a4 may each independently be 0, 1, or 2,
R₂₉ and R₃₀ may each independently be selected from a methyl group, an ethyl group, an n-propyl group, an iso-propyl group, an n-butyl group, a sec-butyl group, an iso-butyl group, a tert-butyl group, an n-pentyl group, an iso-pentyl group, a 1-methylbutyl group, a 2-methylbutyl group, a neo-pentyl group, a 1,2-dimethylpropyl group, a tert-pentyl group, and a phenyl group, but embodiments of the present disclosure are not limited thereto.

A deuteration rate of the composition containing the organometallic compound may be about 50% or more. The deuteration rate may be calculated by using Equation 2:

deuteration rate (%)=n_{D2}/(n_{H2}+n_{D2})×100. Equation 2

In Equation 2,
n_{H2} represents the sum of a total number of hydrogens included in the deuterium-containing substituents in the first organometallic compound and a total number of hydrogens included in the deuterium-free substituent of the second organometallic compound corresponding to the deuterium-containing substituent in the first organometallic compound, and
n_{D2} represents a total number of deuterium atoms included in the deuterium-containing substituents in the first organometallic compound.

When a substituent indicated by a dashed box in Compound 4 is a deuterium-containing substituent, a deuterium-free substituent corresponding to the deuterium-containing substituent in Compound 4′ may mean a substituent indicated by a dashed box in Compound 4′. That is, in the present disclosure, substituents bonded to carbon at the same position in two compounds that differ from each other only in terms of the presence or absence of isotope are defined as “corresponding” substituents.

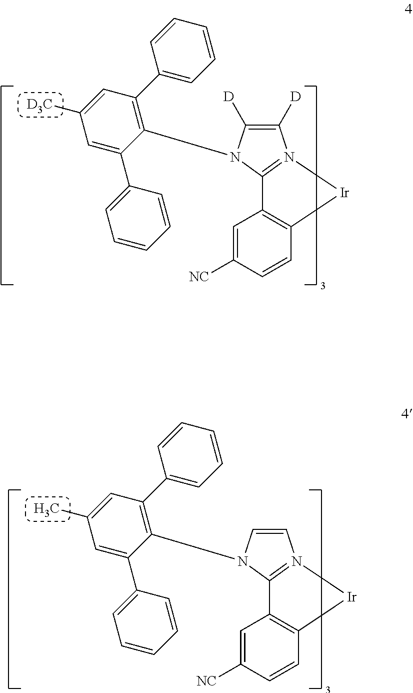

For example, if the first organometallic compound includes two deuterium-containing substituents, n_{D2} means the total number of deuterium atoms included in the two deuterium-containing substituents. Also, n_{H2} means the sum of the number of hydrogens included in the two deuterium-containing substituents and the number of hydrogens included in the deuterium-free substituent of the second organometallic compound corresponding to the two deuterium-containing substituents.

In one or more embodiments, the deuteration rate may be about 70% or more, about 90% or more, about 95% or more, about 96% or more, about 97% or more, about 98% or more, or about 99% or more, but embodiments of the present disclosure are not limited thereto.

Synthesis methods of the organometallic compound represented by Formula 1 may be recognizable by one of ordinary skill in the art by referring to Synthesis Examples provided below. The composition containing the organometallic compound is not the addition of at least one second organometallic compound, but may result from an incomplete deuteration in synthesizing the organometallic compound represented by Formula 1. For example, the composition may include a mixture of Compound 3 and a resultant from an incomplete deuteration of Compound 3 or a mixture of Compound 4 and a resultant from an incomplete deuteration of Compound 4, but embodiments of the present disclosure are not limited thereto.

Synthesis methods of the organometallic compound represented by Formula 1 may be recognizable by one of ordinary skill in the art by referring to Synthesis Examples provided below.

The organometallic compound represented by Formula 1 or the composition containing the organometallic compound may be suitable for use as a dopant in an organic layer of an organic light-emitting device, for example, an emission layer in the organic layer.

According to one or more embodiments, an organic light-emitting device may include:
a first electrode;
a second electrode; and
an organic layer disposed between the first electrode and the second electrode,
wherein the organic layer includes an emission layer, and
wherein the organic layer may include at least one organometallic compound represented by Formula 1 or may include a composition containing the organometallic compound.

Since the organic light-emitting device includes the organic layer including the organometallic compound represented by Formula 1 or the composition containing the organometallic compound, the organic light-emitting device may have high efficiency, a long lifespan, and high color purity.

The organometallic compound represented by Formula 1 or the composition containing the organometallic compound may be used between a pair of electrodes of the organic light-emitting device. For example, the organometallic compound represented by Formula 1 or the composition containing the organometallic compound may be included in the emission layer. The organometallic compound or the composition containing the organometallic compound may act as a dopant, and the emission layer may further include a host (that is, an amount of the organometallic compound represented by Formula 1 or the composition containing the organometallic compound is smaller than an amount of the host). In this embodiment, the dopant may emit blue light.

The expression “(an organic layer) includes at least one of organometallic compounds” as used herein may include an embodiment in which “(an organic layer) includes identical organometallic compounds represented by Formula 1” and an embodiment in which “(an organic layer) includes two or more different organometallic compounds represented by Formula 1.”

For example, the organic layer may include, as the organometallic compound, only Compound 1. In this embodiment, Compound 1 may be included in an emission layer of the organic light-emitting device. In one or more embodiments, the organic layer may include, as the organometallic compound, Compound 1 and Compound 2. In these embodiments, Compound 1 and Compound 2 may be included in an identical layer (for example, Compound 1 and Compound 2 all may be included in an emission layer).

The first electrode may be an anode, which is a hole injection electrode, and the second electrode may be a cathode, which is an electron injection electrode; or the first electrode may be a cathode, which is an electron injection electrode, and the second electrode may be an anode, which is a hole injection electrode.

In one or more embodiments, in the organic light-emitting device, the first electrode is an anode, and the second electrode is a cathode, and the organic layer further includes a hole transport region disposed between the first electrode and the emission layer and an electron transport region disposed between the emission layer and the second electrode, wherein the hole transport region includes at least one selected from a hole injection layer, a hole transport layer, and an electron blocking layer, and wherein the electron transport region includes at least one selected from a hole blocking layer, an electron transport layer, and an electron injection layer.

The term “organic layer” as used herein refers to a single layer and/or a plurality of layers between the first electrode and the second electrode of the organic light-emitting device. The “organic layer” may include, in addition to an organic compound, an organometallic complex including metal.

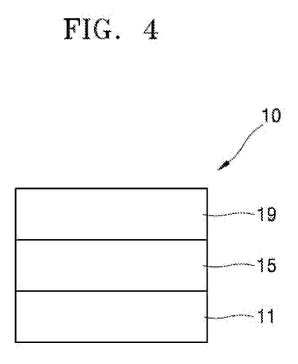

FIG. 4 is a schematic view of an organic light-emitting device 10 according to an embodiment. Hereinafter, the structure of an organic light-emitting device according to an embodiment and a method of manufacturing an organic light-emitting device according to an embodiment will be described in connection with FIG. 4. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode 11 may be, for example, indium tin oxide (ITO), indium zinc oxide (IZO), tin oxide (SnO₂), and zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode 11.

The first electrode 11 may have a single-layered structure or a multi-layered structure including two or more layers. For example, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include at least one selected from a hole injection layer, a hole transport layer, an electron blocking layer, and a buffer layer. The hole transport layer may be a single layer or may include two or more layers.

The hole transport region may include only either a hole injection layer or a hole transport layer. In one or more embodiments, the hole transport region may have a hole injection layer/hole transport layer structure, a hole injection layer/hole transport layer/electron blocking layer structure, a hole transport layer/electron blocking layer structure, a hole injection layer/first hole transport layer/second hole transport layer structure, a hole injection layer/first hole transport layer/second hole transport layer/electron blocking layer structure, or a first hole transport layer/second hole transport layer/electron blocking layer structure, in which layers of each structure may be sequentially stacked on the first electrode 11 in this stated order.

A hole injection layer may be formed on the first electrode 11 by using one or more suitable methods selected from vacuum deposition, spin coating, casting, and Langmuir-Blodgett (LB) deposition.

When a hole injection layer is formed by vacuum deposition, the deposition conditions may vary according to a material that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Angstroms per second (Å/sec) to about 100 Å/sec. However, the deposition conditions are not limited thereto.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include at least one selected from m-MTDATA, TDATA, 2-TNATA, NPB, β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrene sulfonate) (PEDOT/PSS), polyaniline/camphor sulfonic acid (PANI/CSA), polyaniline/poly(4-styrene sulfonate) (PANI/PSS), a compound represented by Formula 201 below, and a compound represented by Formula 202 below:

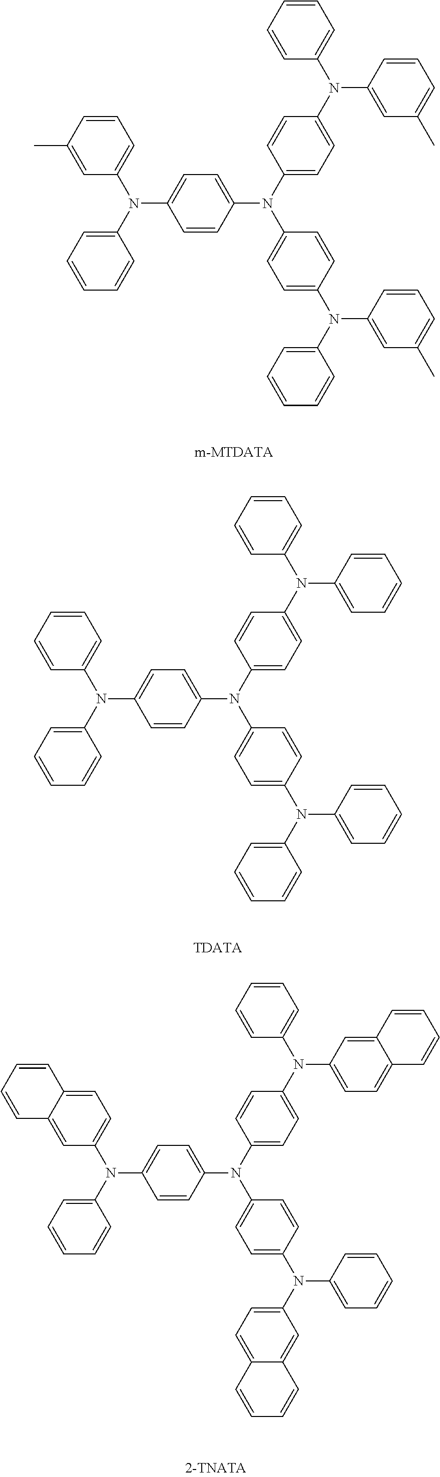

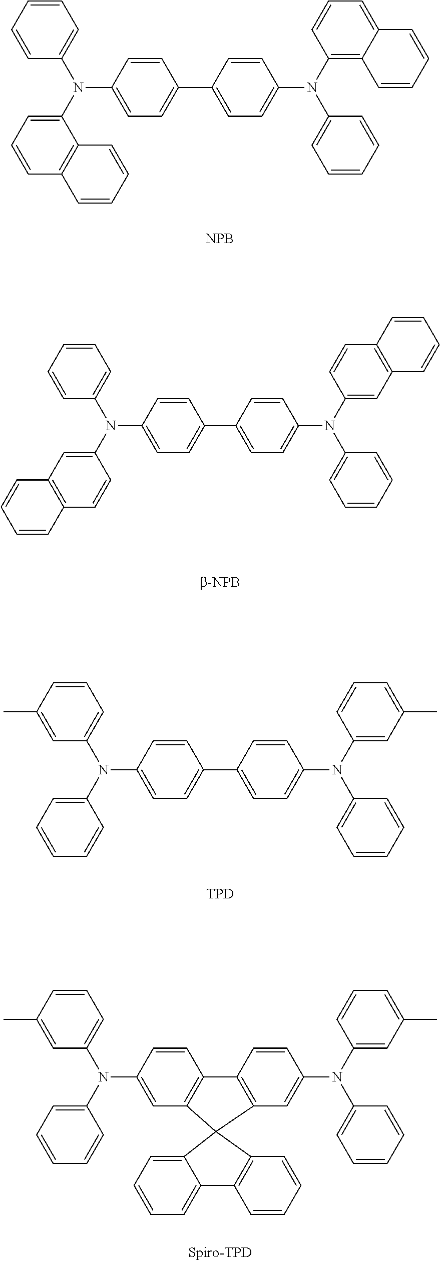

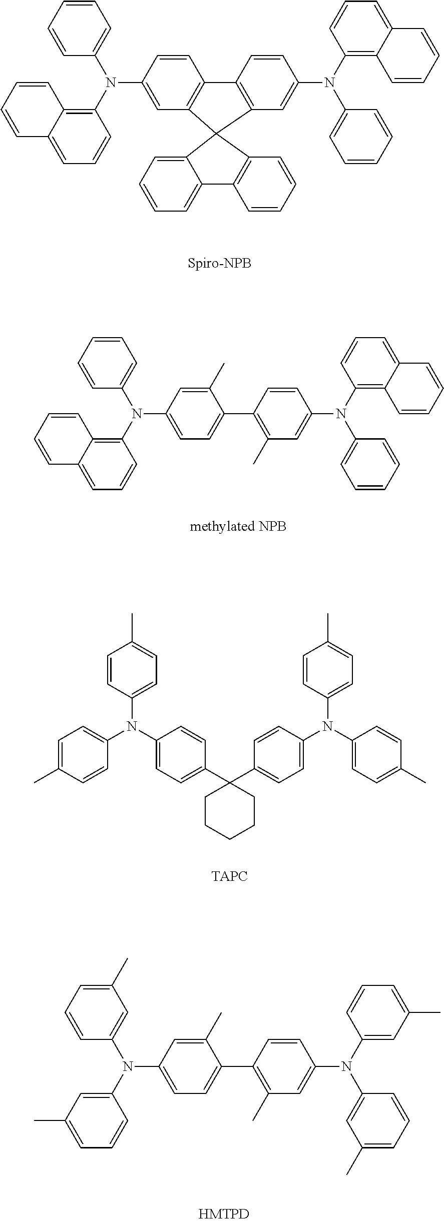

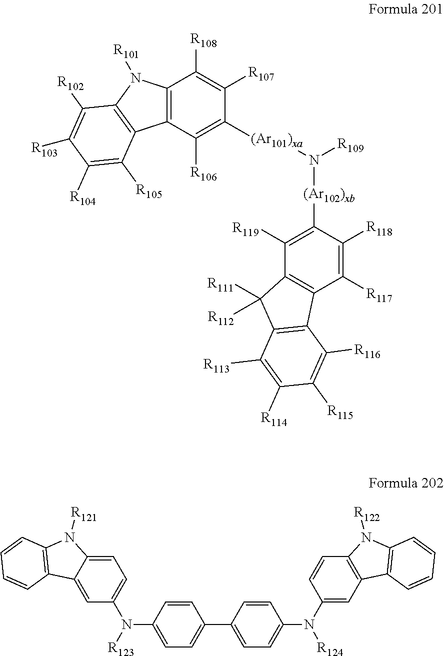

Ar₁₀₁ and Ar₁₀₂ in Formula 201 may each independently be selected from:
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, and a monovalent non-aromatic condensed heteropolycyclic group.

In Formula 201, xa and xb may each independently be an integer from 0 to 5, or 0, 1, or 2. For example, xa is 1 and xb is 0, but xa and xb are not limited thereto.

R₁₀₁ to R₁₀₈, R₁₁₁ to R₁₁₉, and R₁₂₁ to R₁₂₄ in Formulae 201 and 202 may each independently be selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group (for example, a methyl group, an ethyl group, a propyl group, a butyl group, a pentyl group, a hexyl group, and so on), or a C₁-C₁₀ alkoxy group (for example, a methoxy group, an ethoxy group, a propoxy group, a butoxy group, a pentoxy group, and so on);
a C₁-C₁₀ alkyl group or a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;
a phenyl group, a naphthyl group, an anthracenyl group, a fluorenyl group, and a pyrenyl group; and
a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group, but embodiments of the present disclosure are not limited thereto.

R₁₀₉ in Formula 201 may be selected from:
a phenyl group, a naphthyl group, an anthracenyl group, and a pyridinyl group; and
a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, and a pyridinyl group.

According to an embodiment, the compound represented by Formula 201 may be represented by Formula 201A, but embodiments of the present disclosure are not limited thereto:

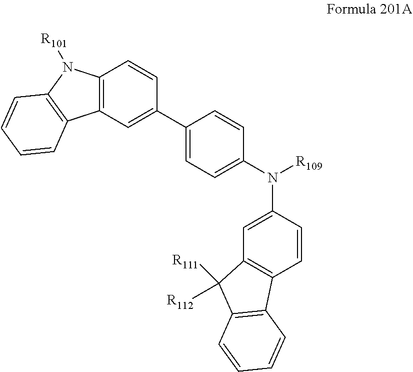

R₁₀₁, R₁₁₁, R₁₁₂, and R₁₀₉ in Formula 201A may be understood by referring to the description provided herein.

For example, the compound represented by Formula 201 and the compound represented by Formula 202 may include compounds HT1 to HT20 illustrated below, but embodiments of the present disclosure are not limited thereto.

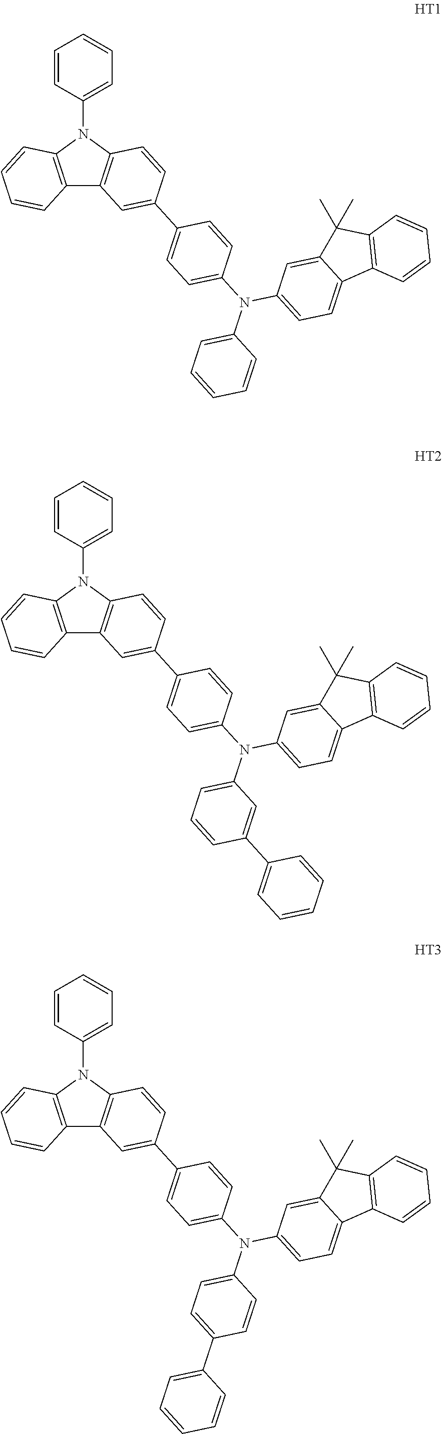 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

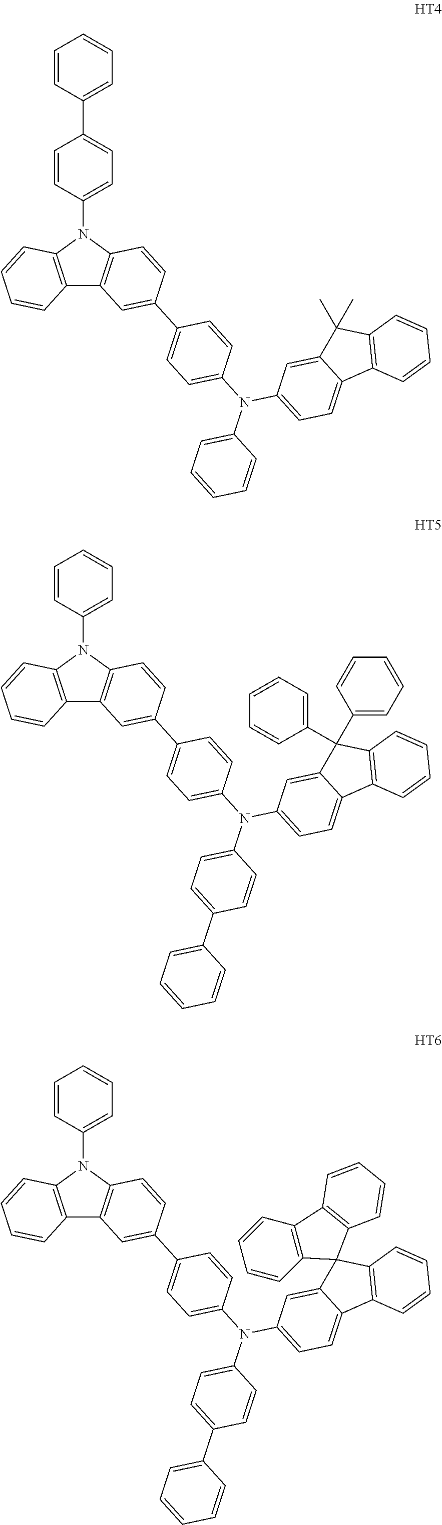 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

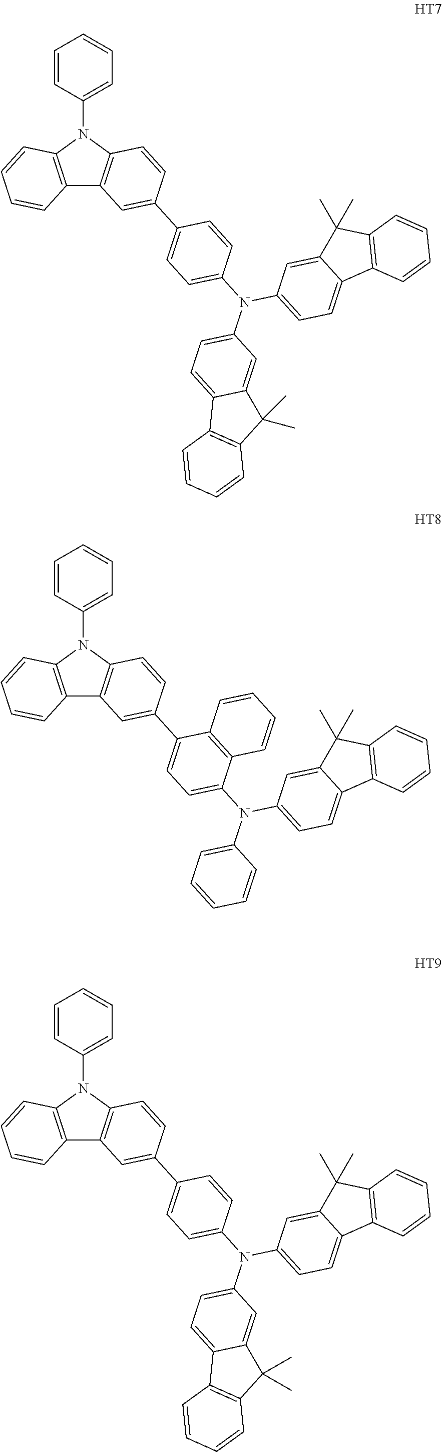 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

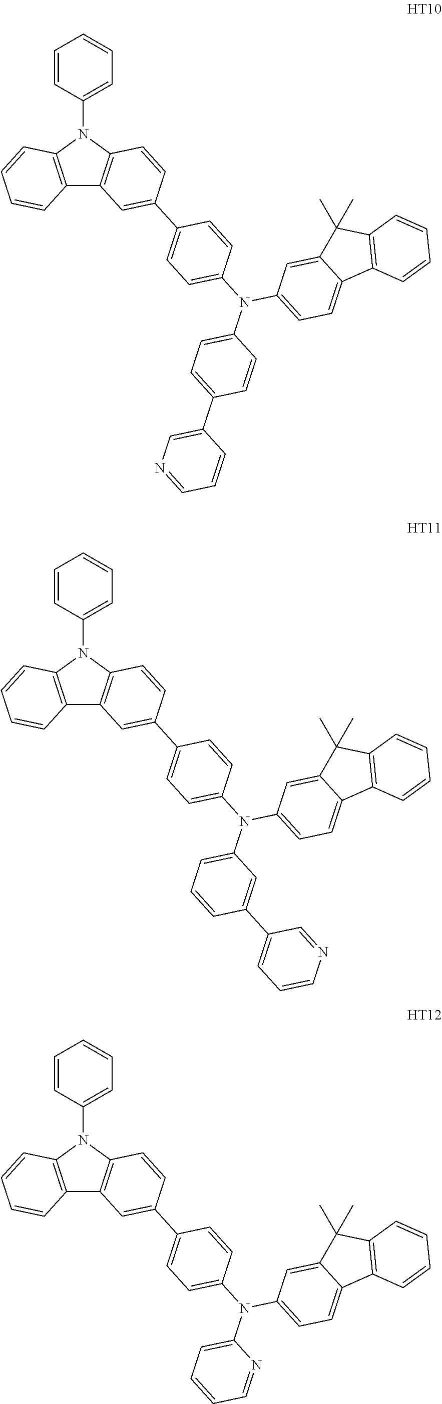 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

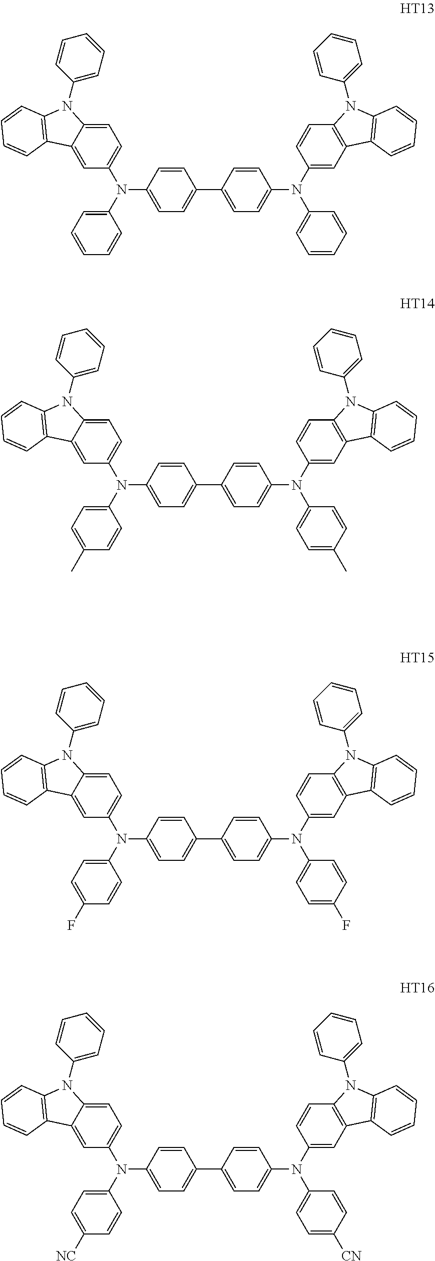 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

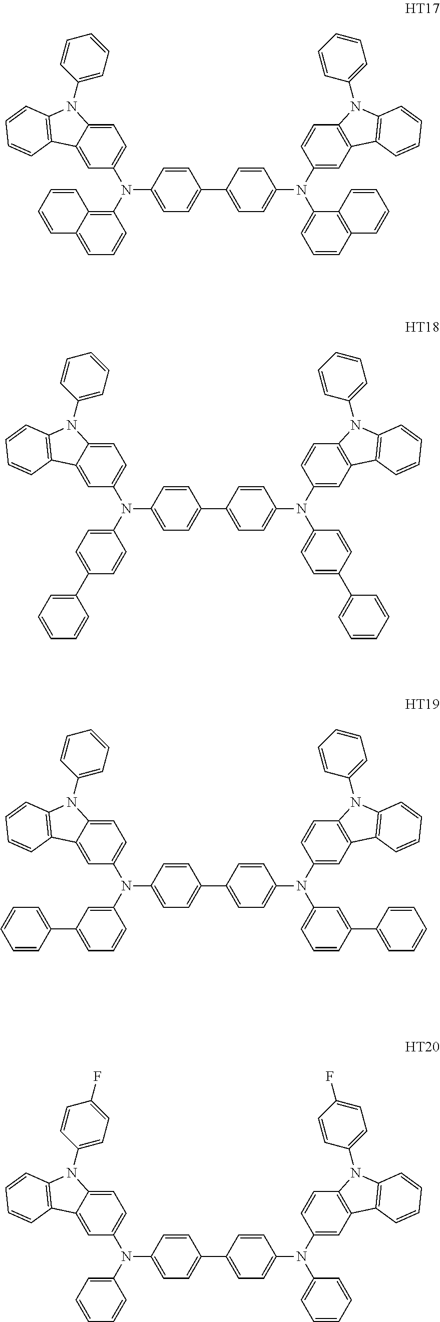 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Angstroms (Å) to about 10,000 Å, for example, about 100 Å to about 1,000 Å. When the hole transport region includes at least one of a hole injection layer and a hole transport layer, the thickness of the hole injection layer may be in a range of about 100 Å to about 10,000 Å, and for example, about 100 Å to about 1,000 Å, and the thickness of the hole transport layer may be in a range of about 50 Å to about 2,000 Å, and for example, about 100 Å to about 1,500 Å. While not wishing to be bound by theory, it is understood that when the thicknesses of the hole transport region, the hole injection layer and the hole transport layer are within these ranges, satisfactory hole transporting characteristics may be obtained without a substantial increase in driving voltage.

The hole transport region may further include, in addition to these materials, a charge-generation material for improving conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenum oxide; and a cyano group-containing compound, such as Compound HT-D1 or Compound HT-D2 below, but embodiments of the present disclosure are not limited thereto.

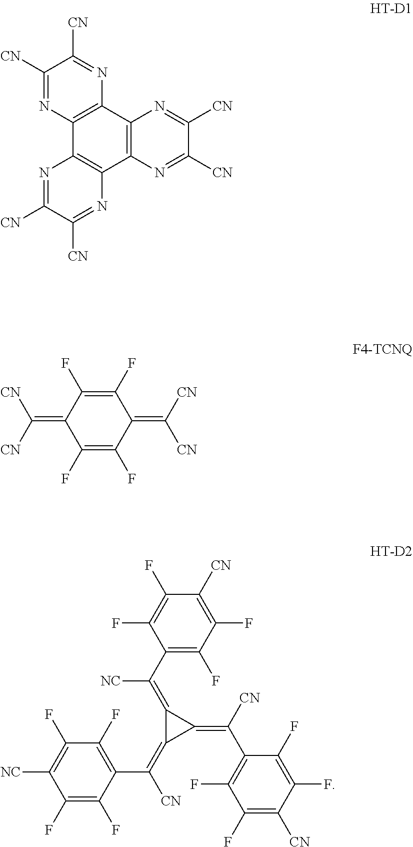

The hole transport region may include a buffer layer.

Also, the buffer layer may compensate for an optical resonance distance according to a wavelength of light emitted from the emission layer, and thus, efficiency of a formed organic light-emitting device may be improved.

Then, an emission layer may be formed on the hole transport region by vacuum deposition, spin coating, casting, LB deposition, or the like. When the emission layer is formed by vacuum deposition or spin coating, the deposition or coating conditions may be similar to those applied to form the hole injection layer although the deposition or coating conditions may vary according to the material that is used to form the emission layer.

Meanwhile, when the hole transport region includes an electron blocking layer, a material for the electron blocking layer may be selected from materials for the hole transport region described above and materials for a host to be explained later. However, the material for the electron blocking layer is not limited thereto. For example, when the hole transport region includes an electron blocking layer, a material for the electron blocking layer may be mCP, which will be explained later.

The emission layer may include a host and a dopant, and the dopant may include the organometallic compound represented by Formula 1 or a composition containing the organometallic compound.

The host may include at least one selected from TPBi, TBADN, ADN (also referred to as “DNA”), CBP, CDBP, TCP, mCP, Compound H50, and Compound H51:

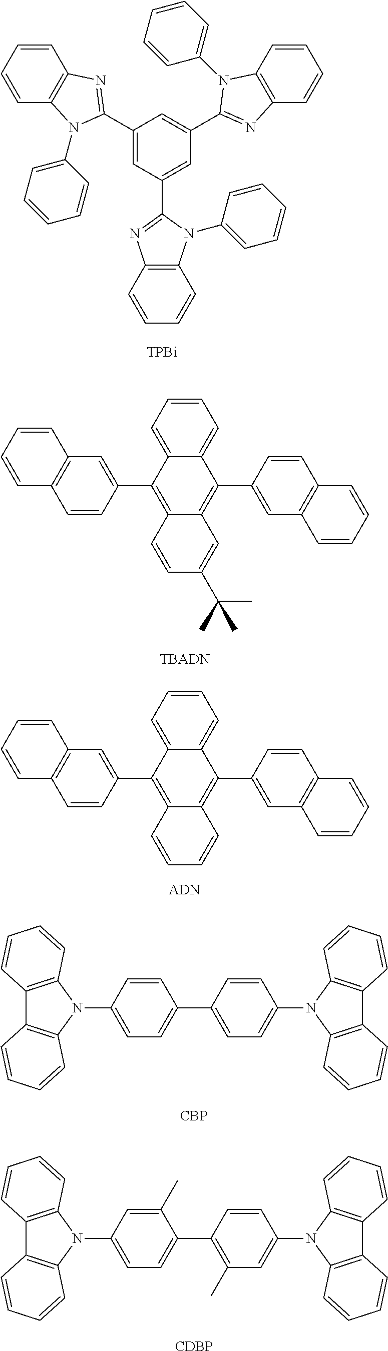

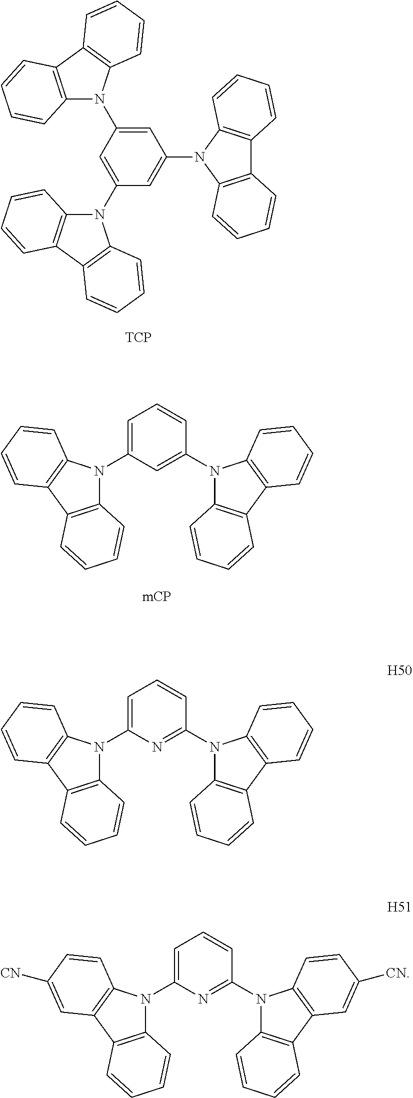

When the organic light-emitting device is a full-color organic light-emitting device, the emission layer may be patterned into a red emission layer, a green emission layer, and a blue emission layer. In one or more embodiments, due to a stack structure including a red emission layer, a green emission layer, and/or a blue emission layer, the emission layer may emit white light.

When the emission layer includes a host and a dopant, an amount of the dopant may be in a range of about 0.01 parts by weight to about 15 parts by weight based on 100 parts by weight of the host, but embodiments of the present disclosure are not limited thereto.

The dopant may include at least one of organometallic compounds represented by Formula 1 or a composition containing the organometallic compound.

A thickness of the emission layer may be in a range of about 100 Å to about 1,000 Å, for example, about 200 Å to about 600 Å. While not wishing to be bound by theory, it is understood that when the thickness of the emission layer is within this range, excellent light-emission characteristics may be obtained without a substantial increase in driving voltage.

Then, an electron transport region may be disposed on the emission layer.

The electron transport region may include at least one selected from a hole blocking layer, an electron transport layer, and an electron injection layer.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP, Bphen, and BAIq but embodiments of the present disclosure are not limited thereto.

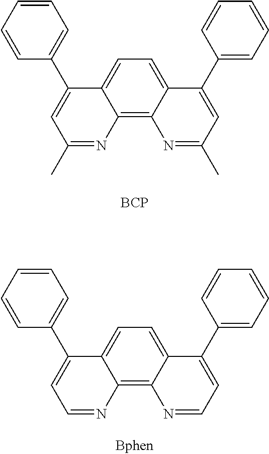 [SMILES: Cc1cc(-c2ccccc2)c2ccc3c(-c4ccccc4)cc(C)nc3c2n1 ; "BCP" ; c1ccc(-c2ccnc3c2ccc2c(-c4ccccc4)ccnc23)cc1]

A thickness of the hole blocking layer may be in a range of about 20 Å to about 1,000 Å, for example, about 30 Å to about 300 Å. While not wishing to be bound by theory, it is understood that when the thickness of the hole blocking layer is within these ranges, the hole blocking layer may have improved hole blocking ability without a substantial increase in driving voltage.

The electron transport layer may include at least one selected from BCP, Bphen, Alq₃, BAIq, TAZ, and NTAZ.

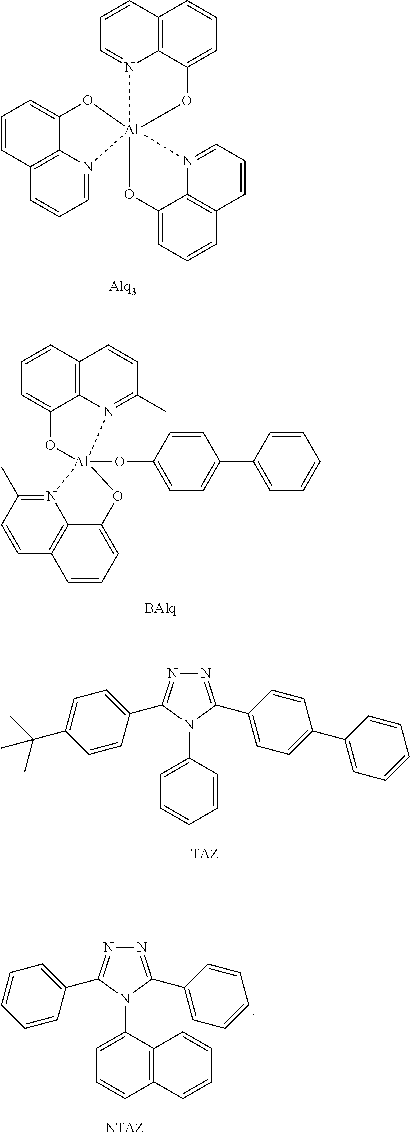

In one or more embodiments, the electron transport layer may include at least one of ET1 to ET19, but embodiments of the present disclosure are not limited thereto:

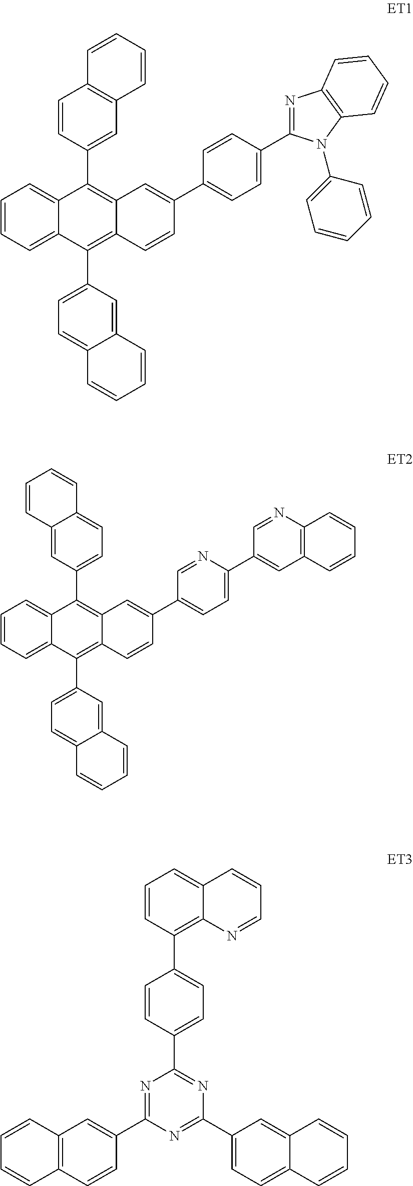 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6cccnc56)cc4)nc(-c4ccc5ccccc5c4)n3)ccc2c1]

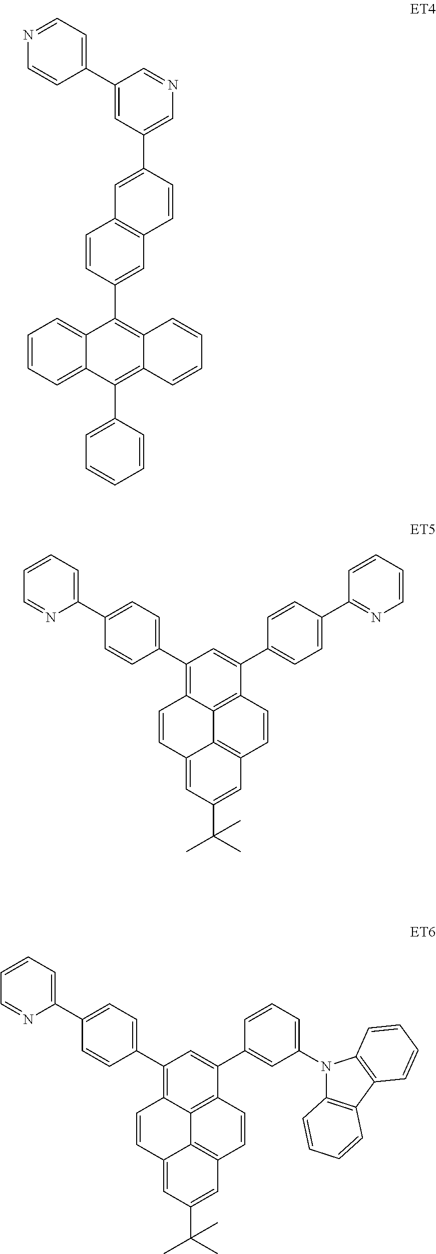 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

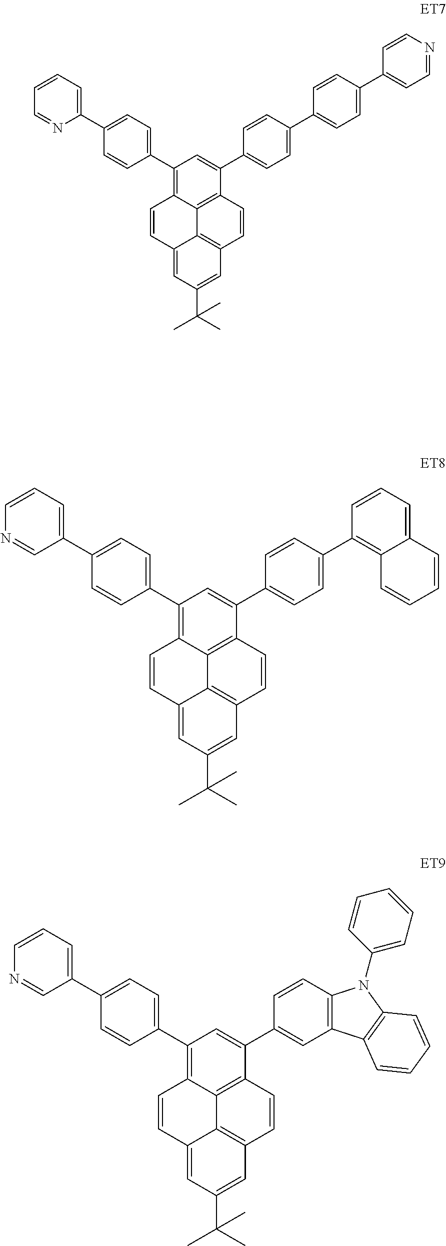 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5cccnc5)cc4)cc(-c4ccc(-c5cccc6ccccc56)cc4)c4ccc(c1)c2c34 ; CC(C)(C)c1cc2ccc3c(-c4ccc(-c5cccnc5)cc4)cc(-c4ccc5c(c4)c4ccccc4n5-c4ccccc4)c4ccc(c1)c2c34]

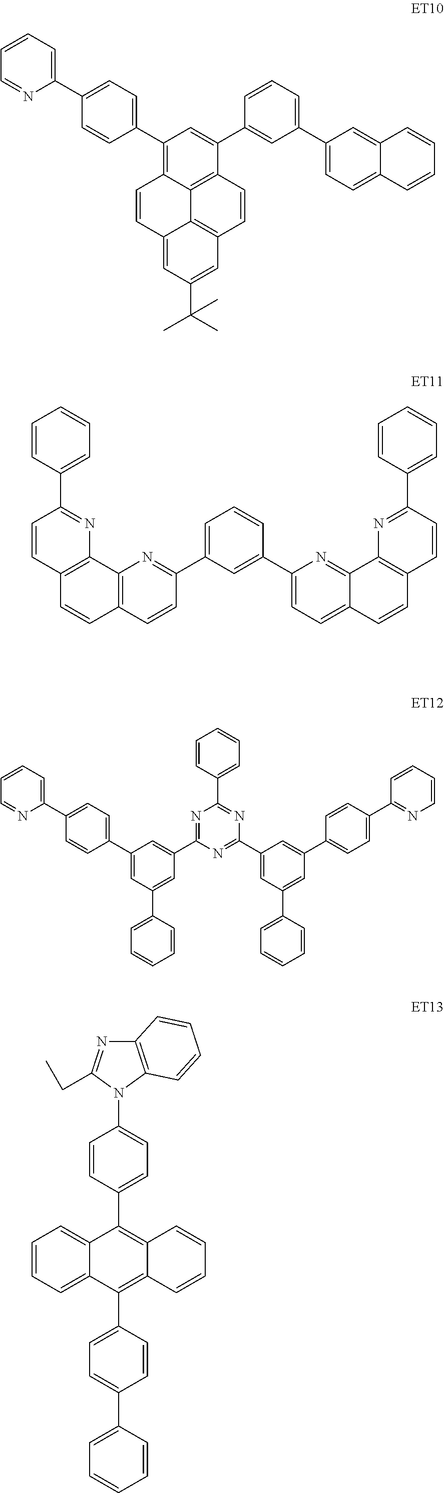 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1 ; CCc1nc2ccccc2n1-c1ccc(-c2c3ccccc3c(-c3ccc(-c4ccccc4)cc3)c3ccccc23)cc1]

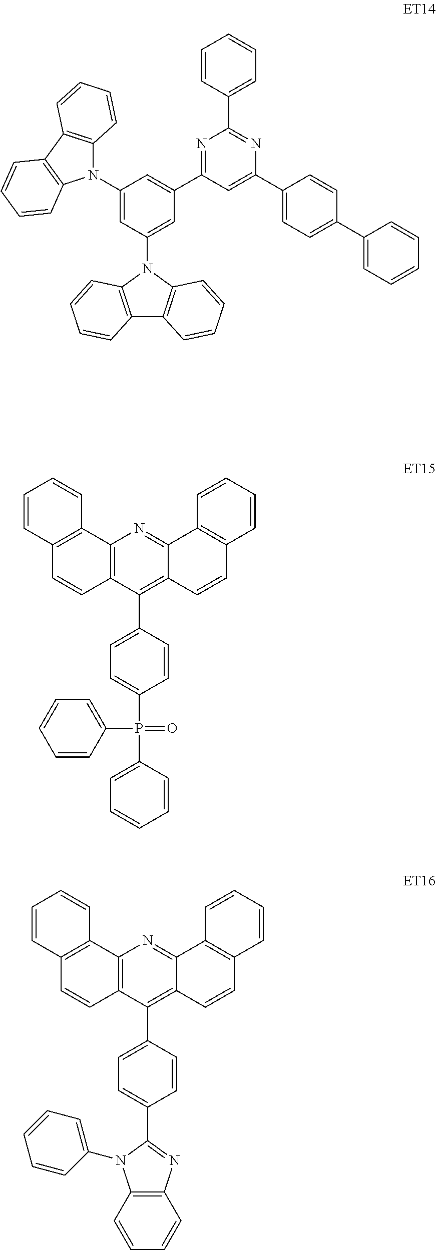 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1 ; c1ccc(-n2c(-c3ccc(-c4c5ccc6ccccc6c5nc5c4ccc4ccccc45)cc3)nc3ccccc32)cc1]

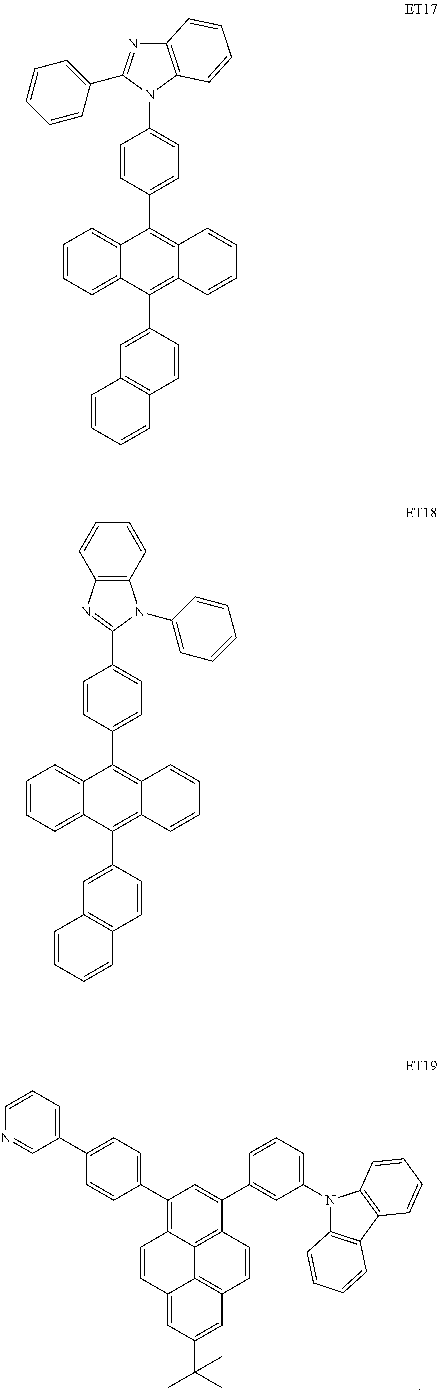 [SMILES: c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1 ; CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. While not wishing to be bound by theory, it is understood that when the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium 8-hydroxyquinolate, LiQ) or ET-D2.

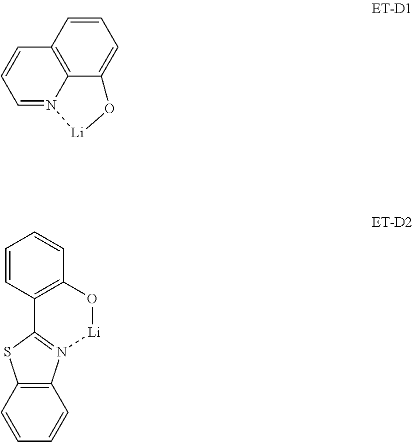

The electron transport region may include an electron injection layer that promotes flow of electrons from the second electrode 19 thereinto.

The electron injection layer may include at least one selected from LiF, NaCl, CsF, Li₂O, and BaO.

A thickness of the electron injection layer may be in a range of about 1 Å to about 100 Å, for example, about 3 Å to about 90 Å. While not wishing to be bound by theory, it is understood that when the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be selected from metal, an alloy, an electrically conductive compound, and a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIG. 4, but embodiments of the present disclosure are not limited thereto.

The term “C₁-C₆₀ alkyl group” as used herein refers to a linear or branched saturated aliphatic hydrocarbon monovalent group having 1 to 60 carbon atoms, and non-limiting examples thereof include a methyl group, an ethyl group, a propyl group, an isobutyl group, a sec-butyl group, a tert-butyl group, a pentyl group, an iso-amyl group, and a hexyl group. The term “C₁-C₆₀ alkylene group” as used herein refers to a divalent group having the same structure as the C₁-C₆₀ alkyl group.

The term “C₁-C₆₀ alkoxy group” as used herein refers to a monovalent group represented by —OA₁₀₁ (wherein A₁₀₁ is the C₁-C₆₀ alkyl group), and non-limiting examples thereof include a methoxy group, an ethoxy group, and an isopropyloxy group.

The term “C₂-C₆₀ alkenyl group” as used herein refers to a hydrocarbon group formed by including at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by including at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent hydrocarbon monocyclic group that has 3 to 10 carbon atoms and at least one carbon-carbon double bond in the ring thereof and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in its ring. Examples of the C₁-C₁₀ heterocycloalkenyl group are a 2,3-dihydrofuranyl group and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and a C₆-C₆₀ arylene group as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a heterocyclic aromatic system that has at least one heteroatom selected from N, O, P, Si, and S as a ring-forming atom, and 1 to 60 carbon atoms. The term “C₁-C₆₀ heteroarylene group” as used herein refers to a divalent group having a heterocyclic aromatic system that has at least one heteroatom selected from N, O, P, Si, and S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₆-C₆₀ aryloxy group” as used herein indicates —OA₁₀₂ (wherein A₁₀₂ is the C₆-C₆₀ aryl group), a C₆-C₆₀ arylthio group as used herein indicates —SA₁₀₃ (wherein A₁₀₃ is the C₆-C₆₀ aryl group), and the term “C₇-C₆₀ arylalkyl group” as used herein indicates —A₁₀₄A₁₀₅ (wherein A₁₀₄ is the C₆-C₅₉ aryl group and A₁₀₅ is the C₁-C₅₃ alkyl group).

The term “C₁-C₆₀ heteroaryloxy group” as used herein refers to —OA₁₀₆ (wherein A₁₀₆ is the C₁-C₆₀ heteroaryl group), and the term “C₁-C₆₀ heteroarylthio group” as used herein indicates —SA₁₀₇ (wherein A₁₀₇ is the C₁-C₆₀ heteroaryl group).

The term “C₂-C₆₀ heteroarylalkyl group” as used herein refers to —A₁₀₈A₁₀₉ (A₁₀₉ is a C₁-C₅₉ heteroaryl group, and A₁₀₈ is a C₁-C₅₉ alkylene group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group” as used herein refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, and S, other than carbon atoms, as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The term “C₅-C₃₀ carbocyclic group” as used herein refers to a monocyclic group or a polycyclic group, and, according to its chemical structure, a monovalent, divalent, trivalent, tetravalent, pentavalent, or hexavalent group.

The term “C₂-C₃₀ heterocyclic group” as used herein refers to a saturated or unsaturated cyclic group having, as a ring-forming atom, at least one heteroatom selected from N, O, Si, P, and S other than 2 to 30 carbon atoms. The term “C₂-C₃₀ heterocyclic group” as used herein refers to a monocyclic group or a polycyclic group, and, according to its chemical structure, a monovalent, divalent, trivalent, tetravalent, pentavalent, or hexavalent group.

At least one substituent of the substituted C₅-C₃₀ carbocyclic group, substituted C₂-C₃₀ heterocyclic group, substituted C₁-C₆₀ alkyl group, substituted C₂-C₆₀ alkenyl group, substituted C₂-C₆₀ alkynyl group, substituted C₁-C₆₀ alkoxy group, substituted C₃-C₁₀ cycloalkyl group, substituted C₁-C₁₀ heterocycloalkyl group, substituted C₃-C₁₀ cycloalkenyl group, substituted C₁-C₁₀ heterocycloalkenyl group, substituted C₆-C₆₀ aryl group, substituted C₆-C₆₀ aryloxy group, substituted C₆-C₆₀ arylthio group, substituted C₇-C₆₀ arylalkyl group, substituted C₁-C₆₀ heteroaryl group, substituted C₁-C₆₀ heteroaryloxy group, substituted C₁-C₆₀ heteroarylthio group, substituted C₂-C₆₀ heteroarylalkyl group, substituted monovalent non-aromatic condensed polycyclic group, and substituted monovalent non-aromatic condensed heteropolycyclic group may be selected from:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), and —P(═O)(Q₁₈)(Q₁₉);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), and —P(═O)(Q₂₈)(Q₂₉); and
—N(Q₃₁)(Q₃₂), —Si(Q₃₃)(Q₃₄)(Q₃₅), —B(Q₃₆)(Q₃₇), and —P(═O)(Q₃₈)(Q₃₉),
wherein Q₁ to Q₉, Q₁₁ to Q₁₉, Q₂₁ to Q₂₉, and Q₃₁ to Q₃₉ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one selected from a C₁-C₆₀ alkyl group and a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group.

When a group containing a specified number of carbon atoms is substituted with any of the groups listed in the preceding paragraph, the number of carbon atoms in the resulting “substituted” group is defined as the sum of the carbon atoms contained in the original (unsubstituted) group and the carbon atoms (if any) contained in the substituent. For example, when the term “substituted C₁-C₃₀ alkyl” refers to a C₁-C₃₀ alkyl group substituted with C₆-C₃₀ aryl group, the total number of carbon atoms in the resulting aryl substituted alkyl group is C₇-C₆₀.

Hereinafter, a compound and an organic light-emitting device according to embodiments are described in detail with reference to Examples. However, the organic light-emitting device is not limited thereto. The wording “B was used instead of A” used in describing Synthesis Examples means that an amount of A used was identical to an amount of B used, in terms of a molar equivalent.

### EXAMPLE

### Synthesis Example 1: Synthesis of Compound 1

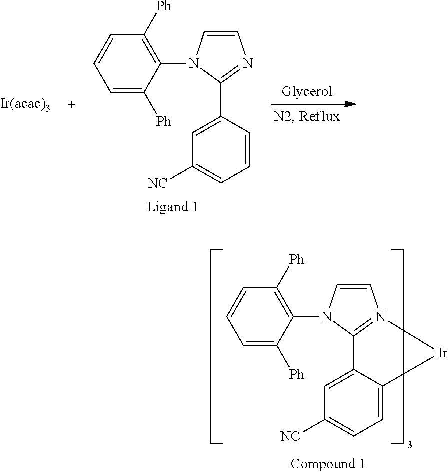

3.29 mmol of Ir(acac)₃, 16.47 mmol of Ligand 1, and glycerol were added to a reaction vessel, and the mixture was refluxed for 12 hours in a nitrogen atmosphere. After the reaction was completed, the resultant mixture was cooled to room temperature, and the organic layer was separated by adding dichloromethane and distilled water. The organic layer was washed twice with distilled water, dried by using MgSO₄, and a solvent was removed under reduced pressure. The crude product was purified by silica gel column chromatography (eluent: dichloromethane and n-hexane) to obtain 0.51 mmol of Compound 1. The structure and purity (99% or more) of Compound 1 were identified by using NMR, HPLC, and LCMS.

1H-NMR (300 MHz, CD₂Cl₂) δ 7.8 (1H, t), 7.7-7.55 (2H, m), 7.1-6.7 (10.5H, m), 6.6 (1H, s), 6.55-6.4 (2H, m).

### Synthesis Example 2: Synthesis of Compound 2

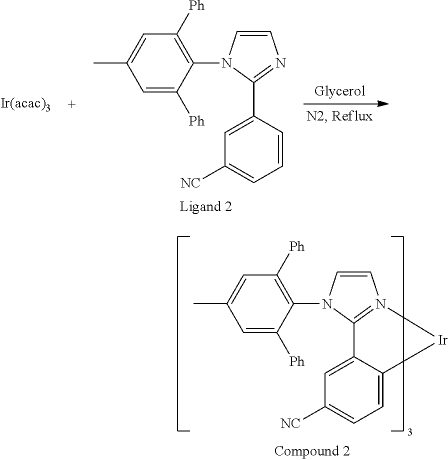

0.50 mmol of Compound 2 was synthesized in the same manner as in Synthesis Example 1, except that Ligand 2 was used instead of Ligand 1. The structure and purity (99% or more) of Compound 2 were identified by using NMR, HPLC, and LCMS.

1H-NMR (300 MHz, CD₂Cl₂) δ 7.50 (1H, s), 7.45 (1H, s), 7.15-6.88 (3H, m), 6.86-6.84 (3H, m), 6.82-6.72 (5H, m), 6.68 (1H, s), 6.46-6.42 (2H, m), 5.46 (1H, s), 2.59 (3H, s)

### Synthesis Example 3: Synthesis of Compound 3

### Synthesis of Ligand 3

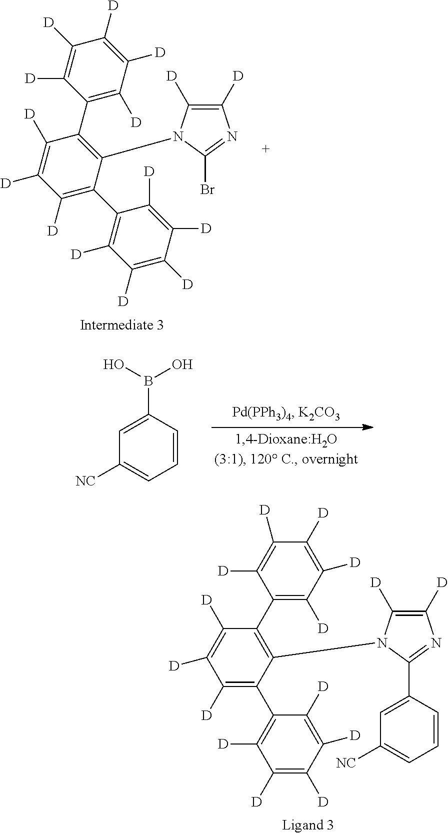 [SMILES: [2H]c1nc(Br)n(-c2c(-c3c([2H])c([2H])c([2H])c([2H])c3[2H])c([2H])c([2H])c([2H])c2-c2c([2H])c([2H])c([2H])c([2H])c2[2H])c1[2H] ; N#Cc1cccc(B(O)O)c1 ; [2H]c1nc(-c2cccc(C#N)c2)n(-c2c(-c3c([2H])c([2H])c([2H])c([2H])c3[2H])c([2H])c([2H])c([2H])c2-c2c([2H])c([2H])c([2H])c([2H])c2[2H])c1[2H]]

14 mmol (5.5 g) of Intermediate 3, 14 mmol of 3-cyano-phenylboronic acid, 0.45 mmol (0.52 g) of tetrakis-(triphenylphosphine)palladium(0), and 45 mmol (6.21 g) of potassium carbonate were mixed with 120 ml of a mixture of 1,4-dioxane and water (volume ratio: 3:1), and the mixture was refluxed at a temperature of 120° C. for overnight. The reaction mixture was cooled, and the product was extracted with ethyl acetate and water. The organic layer was washed three times with water, dried by using magnesium sulfate, and the solvent was removed under reduced pressure. The crude product obtained therefrom was purified by silica gel column chromatography (eluent: dichloromethane and hexane), thereby obtaining 7 mmol (3.0 g) of Ligand 3.

The structure and purity (99.73% or more) of Ligand 3 were identified by using NMR, HPLC, and LCMS. As a result of NMR analysis, it was identified that a deuterium substitution rate was 79% or more.

1H-NMR (300 MHz, CD₂Cl₂) δ 7.7 (0.11H, s), 7.6 (1H, m), 7.7-7.2 (3H, m), 6.99 (0.11H, s), 6.9 (2H, s), 6.8 (0.1H, s)

### Synthesis of Compound 3

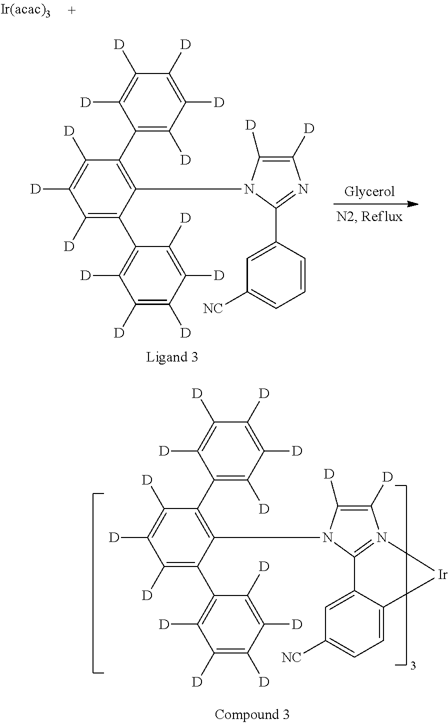

0.55 mmol of Compound 3 was synthesized in the same manner as in Synthesis Example 1, except that Ligand 3 was used instead of Ligand 1. The structure and purity (99% or more) of Compound 3 were identified by using NMR, HPLC, and LCMS.

1H-NMR (300 MHz, CD₂Cl₂) δ 7.80 (0.10H, s), 7.70 (0.08H, s), 7.50 (0.08H, s), 7.10 (0.13H, 7.00 (1H, s), 6.91 (0.10H, s), 6.88 (0.24H, t), 6.85 (1H, s), 6.80-6.75 (0.24H, m), 6.60 (1H, s), 6.50 (0.18H, s), 6.40 (1H, d), 5.45 (0.24H, s)

### Synthesis Example 4: Synthesis of Compound 4

### Synthesis of Ligand 4

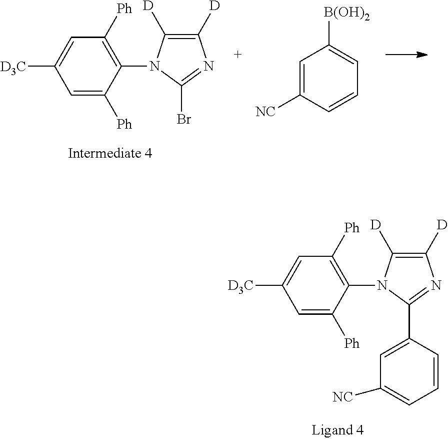 [SMILES: [2H]c1nc(Br)n(-c2c(-c3ccccc3)cc(C([2H])([2H])[2H])cc2-c2ccccc2)c1[2H] ; N#Cc1cccc(B(O)O)c1 ; [2H]c1nc(-c2cccc(C#N)c2)n(-c2c(-c3ccccc3)cc(C([2H])([2H])[2H])cc2-c2ccccc2)c1[2H]]

Ligand 4 was synthesized in the same manner as in Synthesis of Ligand 3 in Synthesis Example 3, except that Intermediate 4 was used instead of Intermediate 3. The structure and deuterium substitution rate of Ligand 4 were identified by using NMR, HPLC, and LCMS.

1H-NMR (300 MHz, CD₂Cl₂) δ 7.5 (0.36H, d), 7.4-7.1 (1.33H, m), 7-6.7 (1H, m), 2.5 (0.16H, s)

### Synthesis of Compound 4

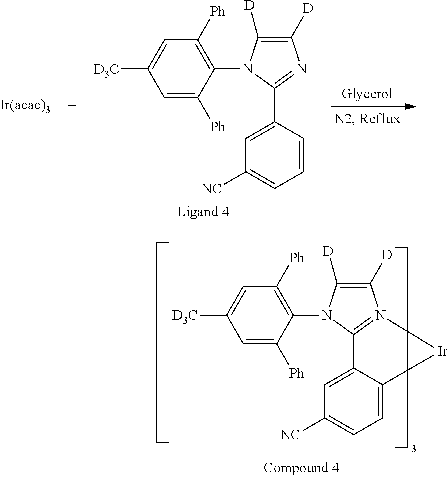

0.53 mmol of Compound 4 was synthesized in the same manner as in Synthesis Example 1, except that Ligand 4 was used instead of Ligand 1. The structure and purity (99% or more) of Compound 4 were identified by using NMR, HPLC, and LCMS.

1H-NMR (300 MHz, CD₂Cl₂) δ 7.47 (0.1H, s), 7.38 (0.1H, s), 7.10-6.65 (4.2H, m), 6.46 (1H, m), 5.5 (0.2H, s), 2.57 (0.39H, s)

### Synthesis Example 5: Synthesis of Compound 5

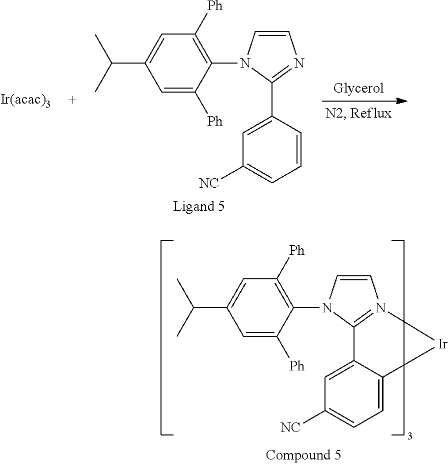

0.50 mmol of Compound 5 was synthesized in the same manner as in Synthesis Example 1, except that Ligand 5 was used instead of Ligand 1. The structure and purity (99% or more) of Compound 5 were identified by using NMR, HPLC, and LCMS.

1H-NMR (300 MHz, CD₂Cl₂) δ 7.50 (1H, s), 7.45 (1H, s), 7.2-6.8 (11.2H, m), 6.7-6.6 (3H, m), 5.46 (1H, s), 3.2 (1H, m), 1.4 (6H, d)

### Synthesis Example 6: Synthesis of Compound 6

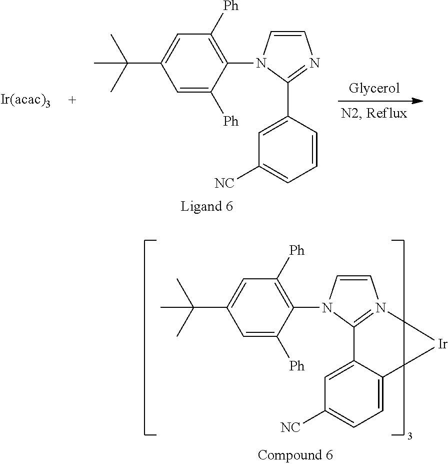

0.51 mmol of Compound 6 was synthesized in the same manner as in Synthesis Example 1, except that Ligand 6 was used instead of Ligand 1. The structure and purity (99% or more) of Compound 6 were identified by using NMR, HPLC, and LCMS.

1H-NMR (300 MHz, CD₂Cl₂) δ 7.65 (1H, s), 7.56 (1H, s), 7.2-7.0 (3H, m), 6.9-6.6 (8H, m), 5.4 (1H, s), 1.47 (9H, s)

### Synthesis Example 7: Synthesis of Compound 7

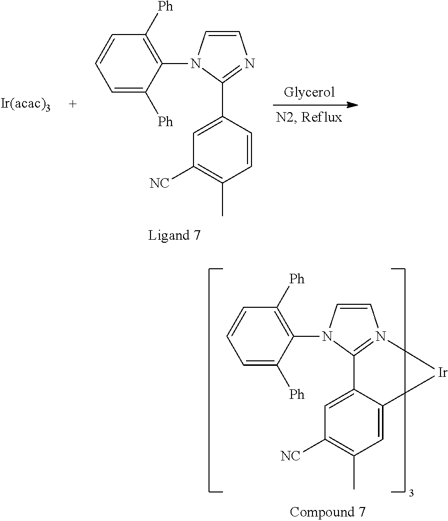

0.53 mmol of Compound 7 was synthesized in the same manner as in Synthesis Example 1, except that Ligand 7 was used instead of Ligand 1. The structure and purity (99% or more) of Compound 7 were identified by using NMR, HPLC, and LCMS.

1H-NMR (300 MHz, CD₂Cl₂) δ 7.50 (1H, s), 7.45 (1H, s), 7.15-6.88 (3H, m), 6.86-6.84 (3H, m), 6.82-6.72 (5H, m), 6.68 (1H, s), 6.46-6.42 (2H, m), 5.46 (1H, s), 2.60 (3H, s)

### Synthesis Example 8: Synthesis of Compound 8

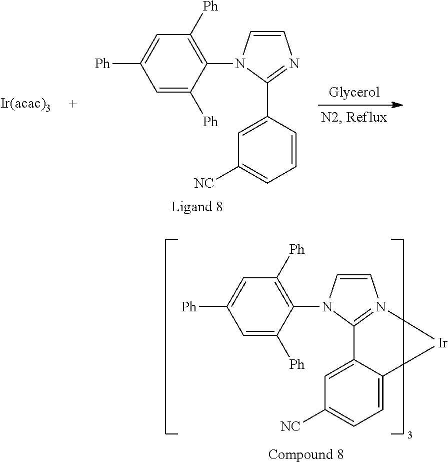

0.48 mmol of Compound 8 was synthesized in the same manner as in Synthesis Example 1, except that Ligand 8 was used instead of Ligand 1. The structure and purity (99% or more) of Compound 8 were identified by using NMR, HPLC, and LCMS.

1H-NMR (300 MHz, CD₂Cl₂) δ 7.8 (1H, s), 7.7 (2H, d), 7.6-7.5 (2H, m), 7.5-7.4 (1H, m), 7.1-7.0 (3H, t), 7.0-6.9 (5H, m), 6.9-6.8 (4H, m), 6.55 (1H, s), 6.5-6.4 (1H, m), 5.5 (1H, s)

### Synthesis Example 9: Synthesis of Compound 9

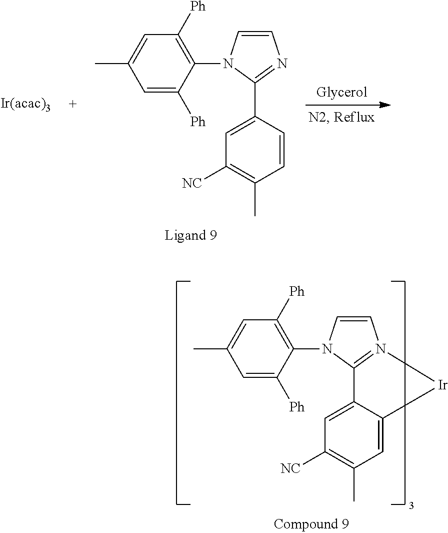

0.5 mmol of Compound 9 was synthesized in the same manner as in Synthesis Example 1, except that Ligand 9 was used instead of Ligand 1. The structure and purity (99% or more) of Compound 9 were identified by using NMR, HPLC, and LCMS.

1H-NMR (300 MHz, CD₂Cl₂) δ 7.50-7.45 (2H, d), 7.15-6.9 (3H, m), 6.85-6.7 (5H, m), 6.7-6.65 (2H, m), 6.6 (1H, s), 6.4 (2H, s), 5.5 (1H, s), 2.6 (3H, s), 2.2 (3H, s)

### Evaluation Example 1: Evaluation of HOMO, LUMO, and Triplet (T₁) Energy Level

The HOMO energy levels, LUMO energy levels, and T₁ energy levels of Compounds 1 to 9, E, and F were evaluated using the methods provided in Table 2.

Results thereof are shown in Table 3.

TABLE 2

| | |
|---|---|
| HOMO energy | After a voltage-current (V-A) graph of each Compound is obtained by |
| level evaluation | using cyclic voltammetry (CV) (electrolyte: 0.1 molar (M) Bu₄NClO₄/ |
| method | solvent: CH₂Cl₂/electrode: three-electrode system (working |
| | electrode: GC, reference electrode: Ag/AgCl, auxiliary electrode: Pt)), |
| | the HOMO energy level of each Compound is calculated from onset |
| | reduction potential of the V-A graph. |
| LUMO energy | After each Compound is diluted with CHCl₃ to a concentration of 1 × 10⁻⁵ M |
| level evaluation | and a UV absorption spectrum is measured at room temperature |
| method | by using a Shimadzu UV-350 Spectrometer, the LUMO energy level |
| | of each Compound is calculated by using an optical band gap (Eg) |
| | from an edge of the UV absorption spectrum. |
| T₁ energy level | After a mixture of toluene and each Compound (1 mg of each |
| evaluation | Compound is dissolved in 3 cc of toluene) is added to a quartz cell |
| method | and then added to liquid nitrogen (77 Kelvins, K), a |
| | photoluminescence (PL) spectrum is measured by using a PL |
| | measurement apparatus. The T₁ energy level is calculated through |
| | analysis of a peak alone observed only at a low temperature by |
| | comparing the PL spectrum with a general room-temperature PL |
| | spectrum. |

TABLE 3

| Compound No. | HOMO (eV) | LUMO (eV) | T₁ (eV) |
|---|---|---|---|
| 1 | −5.26 | −2.60 | 2.66 |
| 2 | −5.24 | −2.57 | 2.67 |
| 3 | −5.26 | −2.60 | 2.66 |
| 4 | −5.24 | −2.57 | 2.67 |
| 5 | −5.28 | −2.62 | 2.66 |
| 6 | −5.26 | −2.60 | 2.66 |
| 7 | −5.20 | −2.52 | 2.68 |
| 8 | −5.26 | −2.60 | 2.66 |
| 9 | −5.14 | −2.45 | 2.69 |
| E | −5.28 | −3.03 | 2.48 |
| F | −5.32 | −3.06 | 2.47 |

It can be confirmed from Table 3 that Compounds 1 to 9 have electrical characteristics suitable for use as materials for an organic light-emitting device. For example, it can be confirmed that Compounds 1 to 9 have relatively higher triplet energy levels than Compounds E and F.

### Evaluation Example 2: Evaluation of PL Spectrum

Light emission characteristics of each Compound were evaluated by evaluating PL spectra of Compounds 1 to 9, E, and F. Compound 1 was diluted with CHCl₃ to a concentration of 10 millimolar (mM), and a PL spectrum was measured at room temperature by using ISC PC1 Spectrofluorometer with a xenon lamp. This process was repeated on Compounds 2 to 9, E, and F.

Maximum wavelengths of the PL spectra of Compounds 1 to 9, E, and F are shown in Table 4.

TABLE 4

| Compound | |
|---|---|
| No. | λₘₐₓ (nm) |
| 1 | 466 |
| 2 | 464 |
| 3 | 466 |
| 4 | 464 |
| 5 | 466 |
| 6 | 466 |
| 7 | 463 |
| 8 | 466 |
| 9 | 461 |
| E | 500 |
| F | 502 |

Referring to Table 4, compounds (Compounds 1 to 9), in which a cyano group is substituted at a para-position with respect to an Ir-carbon bond (Compound 1 to 9), exhibit a maximum emission wavelength of 470 nanometers (nm) or less (for example, 466 nm or less). On the other hand, compounds (Compounds E and F), in which a cyano group is not substituted at a para-position with respect to an Ir-carbon bond, exhibit a maximum emission wavelength greater than 470 nm. It can be seen from these results that deep blue light emission is provided when the cyano group is substituted at the para-position with respect to the Ir-carbon bond. It can be confirmed from Table 4 that Compounds 1 to 9 have excellent light emission characteristics.

### Evaluation Example 3: Evaluation of NPA Charge Value and Open Fraction Value

The NPA charge values of Compounds 1 to 9 and A to F were evaluated by using a DFT method of a Gaussian program that was structurally optimized at a level of B3LYP/6-31G(d,p). Results thereof are shown in Table 5 below. Also, the open fraction value of an atom A of each of Compounds 1 to 9 and A to F (the position of the atom A of each Compound refers to the position of the atom A marked in Compound 1) was evaluated based on Equation 1. Results thereof are shown in Table 5.

TABLE 5

| Compound No. | NPA charge value | Open fraction value |
|---|---|---|
| 1 | 0.4651 | 0.4695 |
| 2 | 0.4654 | 0.4428 |
| 3 | 0.4651 | 0.4695 |
| 4 | 0.4654 | 0.4428 |
| 5 | 0.4728 | 0.4609 |
| 6 | 0.4744 | 0.4581 |
| 7 | 0.4677 | 0.4645 |
| 8 | 0.4579 | 0.4611 |
| 9 | 0.4679 | 0.4650 |
| A | 0.5003 | 0.5488 |
| B | 0.4943 | 0.5006 |
| C | 0.5011 | 0.4941 |
| D | 0.4740 | 0.5030 |
| E | 0.4984 | 0.3654 |
| F | 0.5010 | 0.4880 |

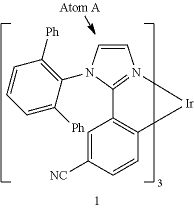

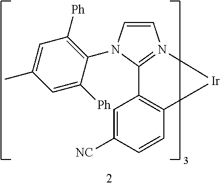

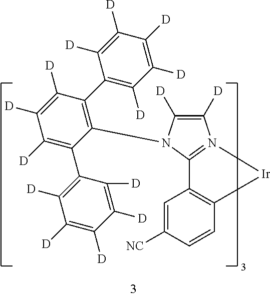

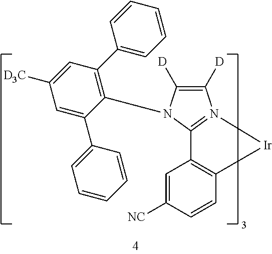

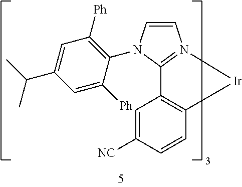

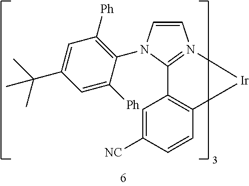

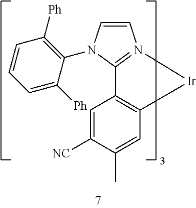

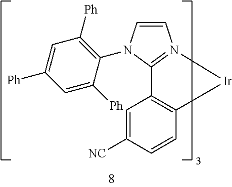

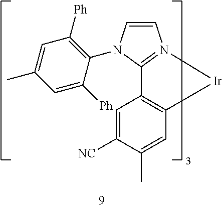

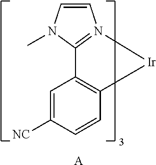

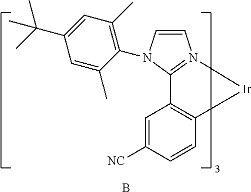

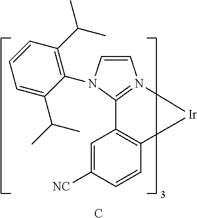

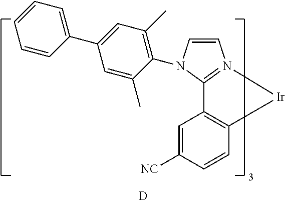

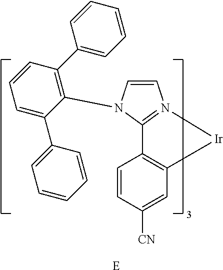

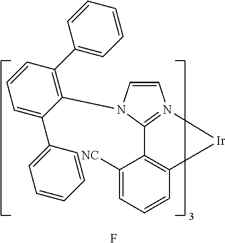

Referring to Table 5, it can be confirmed that Compounds 1 to 9 have relatively small NPA charge values and open fraction values at the same time, as compared with Compounds A to F.

### Example 1

A glass substrate, on which an ITO electrode (first electrode, anode) having a thickness of 1,500 Å was formed, was sonicated with distilled water. After the sonicating with distilled water was completed, the glass substrate was ultrasonically cleaned by sequentially using isopropyl alcohol, acetone, and methanol, was dried, and then transferred to a plasma cleaner. Then, the glass substrate was cleaned for 5 minutes by using oxygen plasma and was provided to a vacuum deposition apparatus.

Compound HT3 was vacuum-deposited on the ITO electrode of the glass substrate to form a first hole injection layer having a thickness of 3,500 Å, Compound HT-D1 was vacuum-deposited on the first hole injection layer to form a second hole injection layer having a thickness of 300 Å, and TAPC was vacuum-deposited on the second hole injection layer to form an electron blocking layer having a thickness of 100 Å, thereby forming a hole transport region.

mCP (host) and Compound 1 (dopant, 7 wt %) were co-deposited on the hole transport region to form an emission layer having a thickness of 300 Å.

Compound ET3 was vacuum-deposited on the emission layer to form an electron transport layer having a thickness of 250 Å, ET-D1 (LiQ) was deposited on the electron transport layer to form an electron injection layer having a thickness of 5 Å, and Al was deposited on the electron injection layer to form a second electrode (cathode) having a thickness of 1,000 Å, thereby completing the manufacture of an organic light-emitting device.

### Examples 2 to 9 and Comparative Examples 1 to 4

Organic light-emitting devices of Examples 2 to 9 and Comparative Examples 1 to 4 were manufactured in the same manner as in Example 1, except that Compounds shown in Table 6 were each used instead of Compound 1 as a dopant in forming an emission layer.

### Evaluation Example 4: Evaluation of Characteristics of Organic Light-Emitting Devices

An EL spectrum, a change in current density according to voltage, a change in luminance according to voltage, conversion efficiency, lifespan, and CIE color coordinates were measured with respect to the organic light-emitting devices manufactured according to Examples 1 to 9 and Comparative Examples 1 to 4. Specific measurement methods are as follows, and results thereof are shown in Table 6.

(1) Measurement of EL Spectrum

The EL spectra of the manufactured organic light-emitting devices were measured by using a luminance meter (Minolta Cs-1000A) at a luminance of 500 candelas per square meter (cd/m²).

(2) Measurement of Change in Current Density According to Voltage

A current value flowing through the manufactured organic light-emitting devices was measured by using a current-voltage meter (Keithley 2400) with respect to the manufactured organic light-emitting devices while increasing a voltage from 0 volts (V) to 10 V, and a current density was obtained by dividing the measured current value by an area.

(3) Measurement of Change in Luminance According to Voltage

Luminance was measured by using a luminance meter (Minolta Cs-1000A) with respect to the manufactured organic light-emitting devices while increasing a voltage from 0 V to 10 V.

(4) Measurement of Conversion Efficiency

Current efficiency (cd/A) of the same current density (10 milliamperes per square centimeter, mA/cm²) was calculated by using the luminance and the current density measured from (2) and (3) and the voltage. Then, conversion efficiency was calculated by dividing the current efficiency by a y value of CIE color coordinates measured in (6).

(5) Measurement of Lifespan

An amount of time (T₉₅) that lapsed when luminance measured from (3) was 95% (T₉₅) of initial luminance (100%) was calculated.

(6) Measurement of CIE Color Coordinates

CIE color coordinates were obtained by measuring EL spectra of the manufactured organic light-emitting devices at a luminance of 500 candelas per square meter (cd/m²) by using a luminance meter (Minolta Cs-1000A).

TABLE 6

| | | | Current | | | | λₘₐₓ in EL | Color |
|---|---|---|---|---|---|---|---|---|
| | Emission layer | | density | Luminance | Efficiency* | T₉₅* | spectrum | coordinates |
| | Host | Dopant | (mA/cm²) | (cd/m²) | (%) | (%) | (nm) | (x, y) |
| Example 1 | mCP | 1 | 10 | 500 | 103 | 350 | 465 | (0.17, 0.33) |
| Example 2 | mCP | 2 | 10 | 500 | 105 | 320 | 465 | (0.17, 0.32) |
| Example 3 | mCP | 3 | 10 | 500 | 103 | 400 | 465 | (0.17, 0.33) |
| Example 4 | mCP | 4 | 10 | 500 | 105 | 370 | 465 | (0.17, 0.32) |
| Example 5 | mCP | 5 | 10 | 500 | 106 | 250 | 465 | (0.17, 0.32) |
| Example 6 | mCP | 6 | 10 | 500 | 106 | 280 | 465 | (0.17, 0.32) |
| Example 7 | mCP | 7 | 10 | 500 | 101 | 220 | 462 | (0.17, 0.30) |
| Example 8 | mCP | 8 | 10 | 500 | 100 | 300 | 466 | (0.18, 0.34) |
| Example 9 | mCP | 9 | 10 | 500 | 100 | 210 | 462 | (0.17, 0.30) |
| Comparative | mCP | A | 10 | 500 | 95 | 30 | 460 | (0.17, 0.26) |
| Example 1 | | | | | | | | |
| Comparative | mCP | B | 10 | 500 | 105 | 80 | 462 | (0.17, 0.30) |
| Example 2 | | | | | | | | |
| Comparative | mCP | C | 10 | 500 | 100 | 100 | 460 | (0.17, 0.26) |
| Example 3 | | | | | | | | |
| Comparative | mCP | D | 10 | 500 | 102 | 115 | 464 | (0.18, 0.31) |
| Example 4 | | | | | | | | |

Efficiency*, T₉₅*: Relative values of efficiency and T₉₅ with respect to those of

### Comparative Example 3

From Table 6, it can be confirmed that the organic light-emitting devices of Examples 1 to 9 emit deep blue light having excellent color purity and have remarkably improved lifespan characteristics, as compared with the organic light-emitting devices of Comparative Examples 1 to 4.

The organometallic compound according to embodiments has excellent electrical characteristics and thermal stability. Accordingly, an organic light-emitting device including the organometallic compound may have excellent driving voltage, current density, efficiency, power, color purity, and lifespan characteristics.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. An organometallic compound represented by Formula 1:
Formula 1 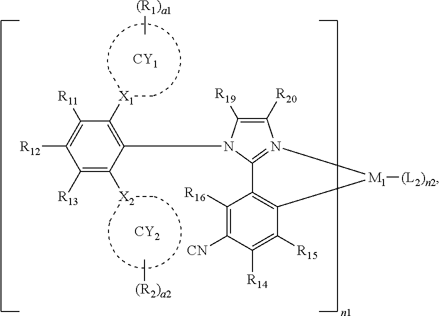
wherein, in Formula 1,
M₁ is selected from a first-row transition metal of the Periodic Table of Elements, a second-row transition metal of the Periodic Table of Elements, and a third-row transition metal of the Periodic Table of Elements,
n1 is 1, 2, or 3,
L₂ is selected from a monodentate ligand and a bidentate ligand,
n2 is 0, 1, 2, 3, or 4, wherein, when n2 is two or more, two or more groups L₂ are identical to or different from each other,
X₁ and X₂ are each independently carbon or nitrogen,
CY₁ and CY₂ are each independently selected from a C₅-C₃₀ carbocyclic group and a C₂-C₃₀ heterocyclic group,
R₁, R₂, and R₁₁ to R₁₆ are each independently selected from hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₁, R₂, R₁₁ to R₁₃, CY₁, and CY₂ are optionally linked to form a substituted or unsubstituted C₅-C₃₀ carbocyclic group or a substituted or unsubstituted C₂-C₃₀ heterocyclic group,
a1 and a2 are each independently an integer from 0 to 5,
R₁₉ and R₂₀ are each independently selected from hydrogen, deuterium, a C₁-C₃₀ alkyl group, a C₁-C₃₀ alkyl group substituted with at least one deuterium, a C₆-C₆₀ aryl group, and a C₆-C₆₀ aryl group substituted with at least one selected from a C₁-C₃₀ alkyl group and deuterium, and
at least one substituent of the substituted C₅-C₃₀ carbocyclic group, the substituted C₂-C₃₀ heterocyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, and the substituted monovalent non-aromatic condensed heteropolycyclic group is selected from:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;
a C₁-C₆₀ alkyl group, a C₂-C₆₀ alkenyl group, a C₂-C₆₀ alkynyl group, and a C₁-C₆₀ alkoxy group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —B(Q₁₆)(Q₁₇), and —P(═O)(Q₁₈)(Q₁₉);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —B(Q₂₆)(Q₂₇), and —P(═O)(Q₂₈)(Q₂₉); and
—N(Q₃₁)(Q₃₂), —Si(Q₃₃)(Q₃₄)(Q₃₅), —B(Q₃₆)(Q₃₇), and —P(═O)(Q₃₈)(Q₃₉),
wherein Q₁ to Q₉, Q₁₁ to Q₁₉, Q₂₁ to Q₂₉, and Q₃₁ to Q₃₉ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryl group substituted with at least one selected from a C₁-C₆₀ alkyl group and a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group.

2. The organometallic compound of claim 1, wherein
M₁ is Ir or Os, and the sum of n1 and n2 is 3 or 4; or
M₁ is Pt, and the sum of n1 and n2 is 2.

3. The organometallic compound of claim 1, wherein
CY₁ and CY₂ are each independently selected from a cyclopentene group, a cyclohexene group, a benzene group, a pyridine group, a pyrimidine group, a pyridazine group, a pyrazine group, a triazine group, a pyrrole group, a pyrazole group, an imidazole group, a triazole group, an oxazole group, an isoxazole group, an oxadiazole group, a thiazole group, an isothiazole group, and a thiadiazole group.

4. The organometallic compound of claim 1, wherein
R₁, R₂, and R₁₁ to R₁₆ are each independently selected from:
hydrogen, deuterium, —F, a cyano group, a nitro group, —SF₅, a methyl group, an ethyl group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group;
a methyl group, an ethyl group, an n-propyl group, an iso-propyl group, an n-butyl group, an isobutyl group, a sec-butyl group, a tert-butyl group, an n-pentyl group, an isopentyl group, a sec-pentyl group, a tert-pentyl group, an n-hexyl group, an iso-hexyl group, a sec-hexyl group, a tert-hexyl group, an n-heptyl group, an iso-heptyl group, a sec-heptyl group, a tert-heptyl group, an n-octyl group, an iso-octyl group, a sec-octyl group, a tert-octyl group, an n-nonyl group, an iso-nonyl group, a sec-nonyl group, a tert-nonyl group, an n-decyl group, an iso-decyl group, a sec-decyl group, a tert-decyl group, a methoxy group, an ethoxy group, a propoxy group, a butoxy group, a pentoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group, each substituted with at least one selected from deuterium, —F, —CD₃, —CD₂H, —CDH₂, —CF₃, —CF₂H, —CFH₂, a cyano group, a nitro group, a C₁-C₁₀ alkyl group, a C₁-C₁₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a naphthyl group, a pyridinyl group, a pyrimidinyl group, a dibenzofuranyl group, and a dibenzothiophenyl group; and
—N(Q₁)(Q₂), —Si(Q₃)(Q₄)(Q₅), —B(Q₆)(Q₇), and —P(═O)(Q₈)(Q₉),
wherein Q₁ to Q₉ are each independently selected from:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, and —CD₂CDH₂;
an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group; and
an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, and a naphthyl group, each substituted with at least one selected from deuterium, a C₁-C₁₀ alkyl group, and a phenyl group.

5. The organometallic compound of claim 1, wherein
R₁, R₂, R₁₁ to R₁₆, R₁₉, and R₂₀ are each independently selected from:
hydrogen, deuterium, —CH₃, —CD₃, —CD₂H, —CDH₂, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, a phenyl group, and groups represented by Formulae 9-1 to 9-24; and
a phenyl group substituted with at least one selected from deuterium, —CD₃, —CD₂H, —CDH₂, and a C₁-C₁₀ alkyl group: 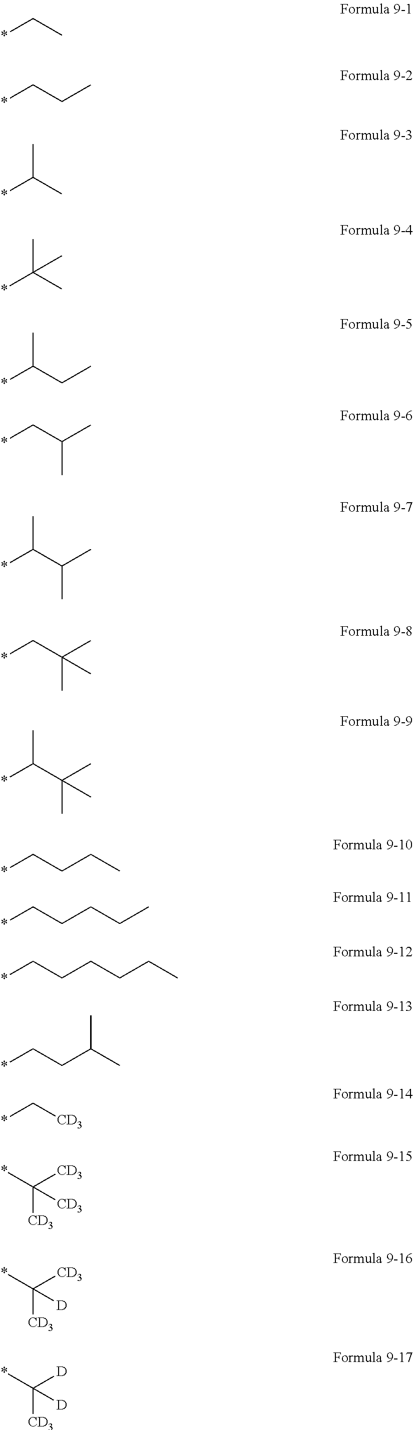 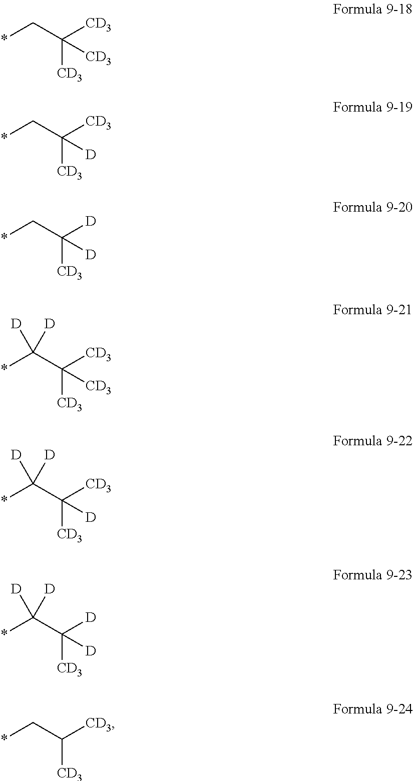
wherein * in Formulae 9-1 to 9-24 indicates a binding site to a neighboring atom.

6. The organometallic compound of claim 1, wherein
at least one of R₁, R₂, R₁₁ to R₁₆, R₁₉, and R₂₀ is a deuterium-containing substituent, and
the deuterium-containing substituent is selected from:
deuterium; and
a C₁-C₂₀ alkyl group and a phenyl group, each substituted with at least one deuterium.

7. The organometallic compound of claim 6, wherein
the deuterium-containing substituent is selected from:
deuterium; and
a methyl group, an ethyl group, an n-propyl group, an iso-propyl group, an n-butyl group, a sec-butyl group, an iso-butyl group, a tert-butyl group, an n-pentyl group, an iso-pentyl group, a 1-methylbutyl group, a 2-methylbutyl group, a neo-pentyl group, a 1,2-dimethylpropyl group, a tert-pentyl group, and a phenyl group, each substituted with at least one deuterium.

8. The organometallic compound of claim 1, wherein
at least one of R₁₂, R₁₄, R₁₉, and R₂₀ is selected from:
deuterium; and
a methyl group, an ethyl group, an n-propyl group, an iso-propyl group, an n-butyl group, a sec-butyl group, an iso-butyl group, a tert-butyl group, an n-pentyl group, an iso-pentyl group, a 1-methylbutyl group, a 2-methylbutyl group, a neo-pentyl group, a 1,2-dimethylpropyl group, a tert-pentyl group, and a phenyl group, each substituted with at least one deuterium.

9. The organometallic compound of claim 1, wherein
R₁₂ and R₁₄ are each independently selected from:
hydrogen, deuterium, —CH₃, —CD₃, —CD₂H, —CDH₂, —CH₂CD₂H, —CH₂CDH₂, —CHDCH₃, —CHDCD₂H, —CHDCDH₂, —CHDCD₃, —CD₂CD₃, —CD₂CD₂H, —CD₂CDH₂, a phenyl group, and groups represented by Formulae 9-1 to 9-24; and
a phenyl group substituted with at least one selected from deuterium, —CD₃, —CD₂H, —CDH₂, and a C₁-C₁₀ alkyl group, and
R₁₉ and R₂₀ are each independently hydrogen or deuterium: 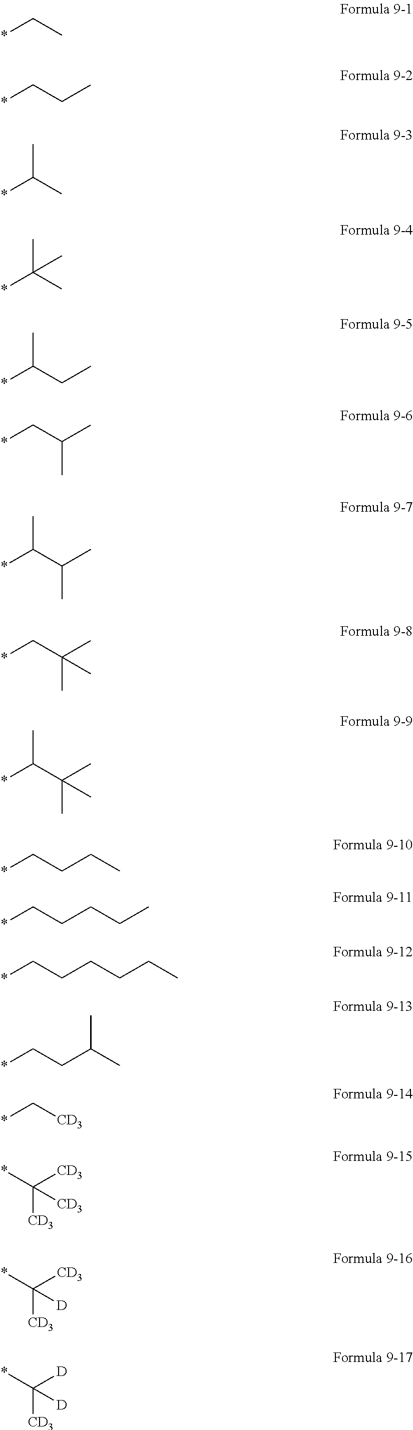 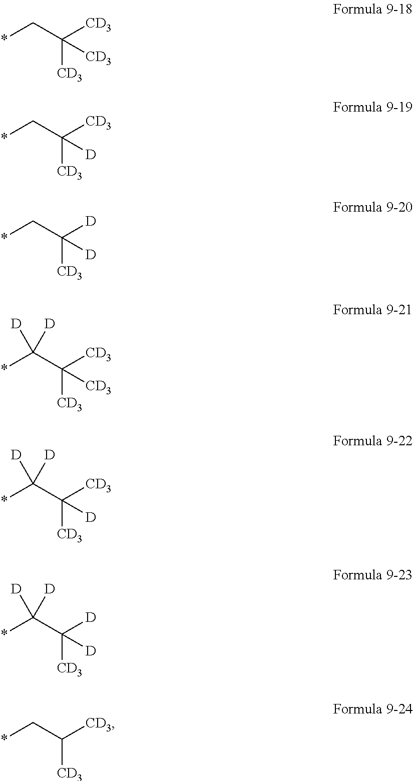
wherein * in Formulae 9-1 to 9-24 indicates a binding site to a neighboring atom.

10. The organometallic compound of claim 1, wherein
the organometallic compound is represented by Formula 1-1: 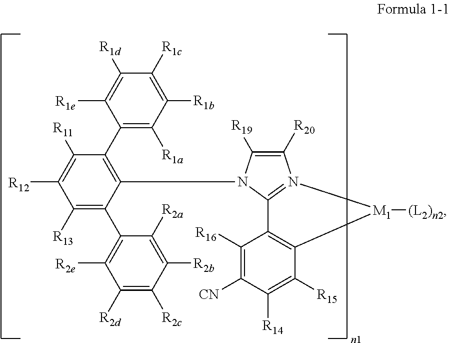
wherein, in Formula 1-1, M₁, n1, L₂, n2, R₁₁ to R₁₆, R₁₉, and R₂₀ are the same as described in claim 1, R₁ₐ to R₁ₑ are the same as described in connection with R₁ in claim 1, and R₂ₐ to R₂ₑ are the same as described in connection with R₂ in claim 1.

11. The organometallic compound of claim 1, wherein
the organometallic compound is represented by Formula 1(1): 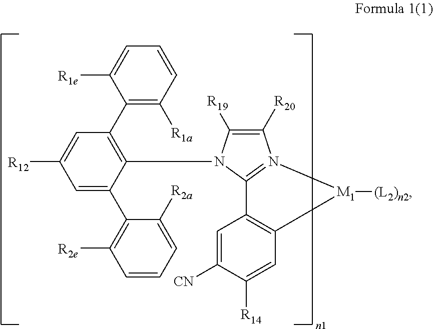
wherein, in Formula 1(1), M₁, n1, L₂, n2, R₁₂, R₁₄, R₁₉, and R₂₀ are the same as described in claim 1, R₁ₐ and R₁ₑ are the same as described in connection with R₁ in claim 1, and R₂ₐ and R₂ₑ are the same as described in connection with R₂ in claim 1.

12. The organometallic compound of claim 1, wherein
L₂ in Formula 1 is selected from ligands represented by Formulae 3A to 3F: 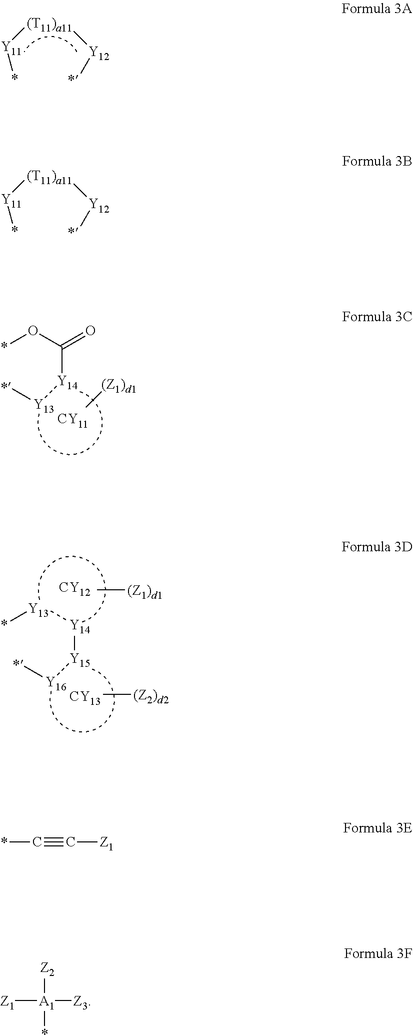
wherein, in Formulae 3A to 3F,
Y₁₁ is selected from O, N, N(Z₁), P(Z₁)(Z₂), and As(Z₁)(Z₂),
Y₁₂ is selected from O, N, N(Z₃), P(Z₃)(Z₄), and As(Z₃)(Z₄),
CY₁₁ is a C₂-C₃₀ heterocyclic group,
T₁₁ is each independently selected from a single bond, a double bond, *—C(Z₁₁)(Z₁₂)—*′, *—C(Z₁₁)═C(Z₁₂)—*′, *═C(Z₁₁)—*′, *—C(Z₁₁)═*′, *═C(Z₁₁)—C(Z₁₂)═C(Z₁₃)—*′, *—C(Z₁₁)═C(Z₁₂)—C(Z₁₃)═*′, *—N(Z₁₁)—*′, and a substituted or unsubstituted C₅-C₃₀ carbocyclic group,
a11 is an integer from 1 to 10,
Y₁₃ to Y₁₆ is each independently carbon (C) or nitrogen (N), Y₁₃ and Y₁₄ are linked via a single bond or a double bond, and Y₁₅ and Y₁₆ are linked via a single bond or a double bond,
CY₁₂ and CY₁₃ are each independently selected from a C₅-C₃₀ carbocyclic group and a C₂-C₃₀ heterocyclic group,
A₁ is P or As,
Z₁ to Z₄ and Z₁₁ to Z₁₃ are each independently selected from hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
d1 and d2 are each independently an integer from 0 to 10, and
* and *′ each indicate a binding site to M in Formula 1.

13. The organometallic compound of claim 1, wherein
the organometallic compound is one of Compounds 1 to 9: 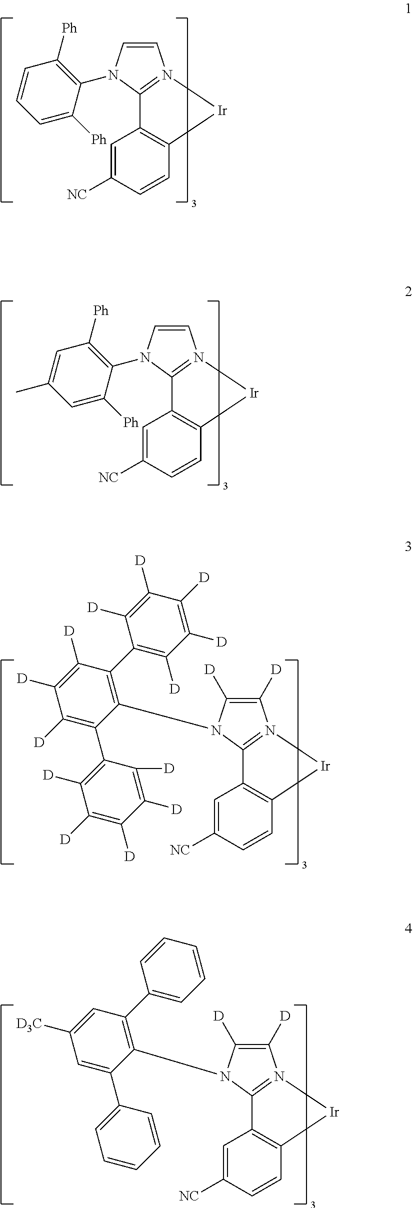 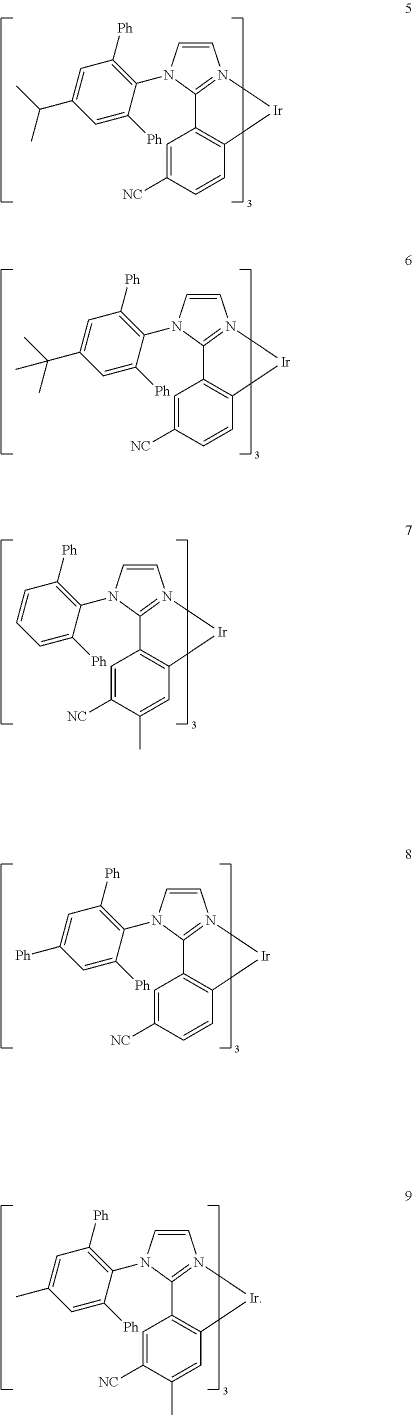
wherein “Ph” in Compounds 1 to 9 indicates a phenyl group.

14. The organometallic compound of claim 1, wherein
the organometallic compound has a natural population analysis (NPA) charge value of about 0.48 or less, and
the NPA charge value is evaluated by a density functional theory (DFT) method using a Gaussian program that is structurally optimized at a level of B3LYP/6-31G(d,p).

15. The organometallic compound of claim 1, wherein
an open fraction value of atom A bonded to R₁₉ of Formula 1 is about 0.5 or less, and the open fraction value is calculated by using Equation 1:
Open Fraction values=Area_{screened}/Area_{free}, Equation 1
wherein, in Equation 1,
Area_{free} represents an area of a two-dimensional figure obtained by projecting the atom A on a plane A and is calculated by π×(van der Waals radius of the atom A)²,
Area_{screened} represents an average value of an area of a two-dimensional figure obtained by projecting the atom A screened by another atom B of Formula 1 on a plane B,
assuming that the atom A and the atom B each have a spherical shape,
the plane B is planes in which vectors directing from 492 points on a spherical surface of a sphere tessellation toward an origin of the sphere tessellation are normal vectors, and
Area_{screened} is calculated by a density functional theory (DFT) method using a Gaussian program that is structurally optimized at a level of B3LYP/6-31G(d,p).

16. A composition containing an organometallic compound, the composition comprising:
a first organometallic compound represented by Formula 1; and
a second organometallic compound represented by Formula 2: 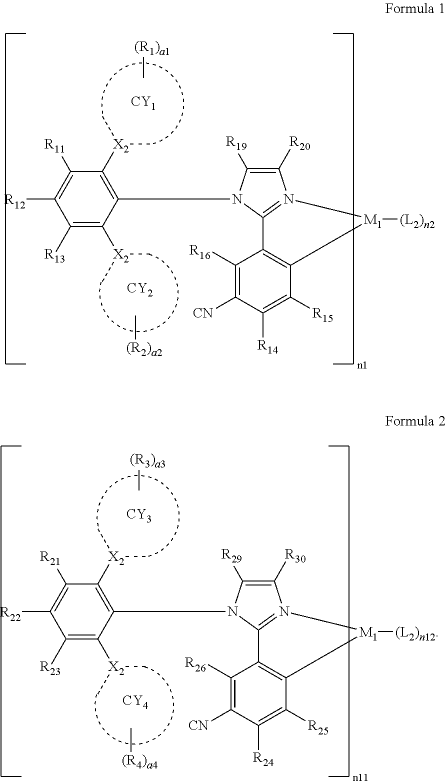 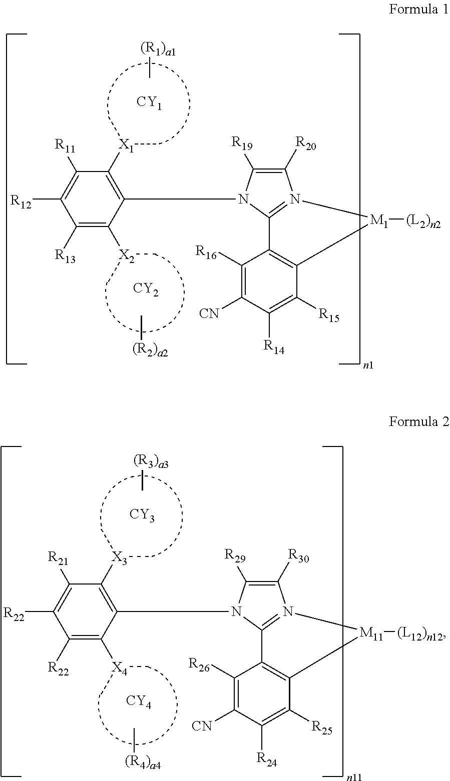
wherein, in Formulae 1 and 2,
M₁ and M₁₁ are each independently selected from a first-row transition metal of the Periodic Table of Elements, a second-row transition metal of the Periodic Table of Elements, and a third-row transition metal of the Periodic Table of Elements,
n1 and n11 are each independently 1, 2, or 3,
L₂ and L₁₂ are each independently selected from a monodentate ligand and a bidentate ligand,
n2 and n12 are each independently 0, 1, 2, 3, or 4, wherein, when n2 is two or more, two or more groups L₂ are identical to or different from each other, and when n12 is two or more, two or more groups L₁₂ are identical to or different from each other,
X₁ to X₄ are each independently carbon or nitrogen,
CY₁ to CY₄ are each independently selected from a C₅-C₃₀ carbocyclic group and a C₂-C₃₀ heterocyclic group,
R₁, R₂, and R₁₁ to R₁₆ are each independently selected from hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₁, R₂, R₁₁ to R₁₃, CY₁, and CY₂ are optionally linked to form a substituted or unsubstituted C₅-C₃₀ carbocyclic group or a substituted or unsubstituted C₂-C₃₀ heterocyclic group,
a1 and a2 are each independently an integer from 0 to 5,
R₁₉ and R₂₀ are each independently selected from hydrogen, deuterium, a C₁-C₃₀ alkyl group, a C₁-C₃₀ alkyl group substituted with at least one deuterium, a C₆-C₆₀ aryl group, and a C₆-C₆₀ aryl group substituted with at least one selected from a C₁-C₃₀ alkyl group and deuterium,
at least one of R₁, R₂, R₁₁ to R₁₆, R₁₉, and R₂₀ is a deuterium-containing substituent,
R₃, R₄, and R₂₁ to R₂₆ are each independently selected from hydrogen, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₇-C₆₀ arylalkyl group, a substituted or unsubstituted C₁-C₆₀ heteroaryl group, a substituted or unsubstituted C₁-C₆₀ heteroaryloxy group, a substituted or unsubstituted C₁-C₆₀ heteroarylthio group, a substituted or unsubstituted C₂-C₆₀ heteroarylalkyl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₅), —B(Q₆)(Q₇), and —P(═O)(Q₈)(Q₉),
two or more neighboring groups of R₃, R₄, R₂₁ to R₂₃, CY₃, and CY₄ are optionally linked to form a substituted or unsubstituted C₅-C₃₀ carbocyclic group or a substituted or unsubstituted C₂-C₃₀ heterocyclic group,
a3 and a4 are each independently an integer from 0 to 5,
R₂₉ and R₃₀ are each independently selected from hydrogen, a C₁-C₃₀ alkyl group, a C₆-C₆₀ aryl group, and a C₆-C₆₀ aryl group substituted with at least one C₁-C₃₀ alkyl group, and
R₃, R₄, R₂₁ to R₂₆, R₂₉, and R₃₀ are each a deuterium-free substituent.

17. The composition of claim 16, wherein
a deuteration rate represented by Equation 2 is about 50% or more:
deuteration rate (%)=n_{D2}/(n_{H2}+n_{D2})×100, Equation 2
wherein, in Equation 2,
n_{H2} represents the sum of a total number of hydrogens included in deuterium-containing substituents in the first organometallic compound and a total number of hydrogens included in a deuterium-free substituent of the second organometallic compound corresponding to the deuterium-containing substituent in the first organometallic compound, and
n_{D2} represents a total number of deuterium atoms included in the deuterium-containing substituents in the first organometallic compound.

18. The composition of claim 16, wherein
the composition comprises a mixture of Compound 3 and a resultant from an incomplete deuteration of Compound 3 or a mixture of Compound 4 and a resultant from an incomplete deuteration of Compound 4:

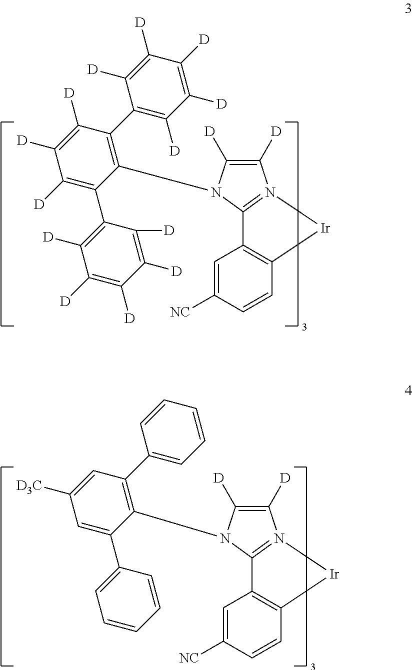

19. An organic light-emitting device comprising:
a first electrode;
a second electrode; and
an organic layer disposed between the first electrode and the second electrode,
wherein the organic layer comprises an emission layer, and
wherein the organic layer comprises at least one organometallic compound of claim 1 or the composition of claim 16.

20. The organic light-emitting device of claim 19, wherein
the emission layer comprises the organometallic compound or the composition.

21. The organic light-emitting device of claim 20, wherein
the emission layer further comprises a host.
